(19) United States
(12) Patent Application Publication
(10) Pub. No.: US 2026/0304849 A1
(43) Pub. Date: Oct. 1, 2026

(54) STRAIN ENGINEERING USING FIN ISOLATION STRUCTURES

(71) Applicant: Intel Corporation, Santa Clara, CA (US)

(72) Inventors: Xia Li, San Diego, CA (US); Marko Radosavljevic, Portland, OR (US); Yang Zhang, Rio Rancho, NM (US); Leonard P. Guler, Hillsboro, OR (US); Charles H. Wallace, Portland, OR (US); Bilal Chehab, Portland, OR (US); Prashanth Aprameyan, San Jose, CA (US)

(73) Assignee: Intel Corporation, Santa Clara, CA (US)

(21) Appl. No.: 19/092,417

(22) Filed: Mar. 27, 2025

(51) Int. Cl. H10D 30/69; H10D 30/00; H10D 30/01; H10D 30/43; H10D 30/47; H10D 62/10; H10D 84/01; H10D 84/83

(52) U.S. Cl. CPC H10D 30/792; H10D 30/47; H10D 30/502; H10D 30/795; H10D 62/121; H10D 84/832; H10D 30/014; H10D 30/017; H10D 30/0191; H10D 30/43; H10D 84/0151

(57) ABSTRACT

Techniques to form semiconductor devices that include one or more fin isolation structures. Different ones of the fin isolation structures are configured with diverse materials, relative to other ones of the fin isolation structures, such that they cause or otherwise impose beneficial stress (e.g., tensile or compressive) on the adjacent semiconductor devices to improve performance. The semiconductor regions of devices may be interrupted with a fin isolation structure that includes dielectric material to electrically isolate the portions of the semiconductor region on either side of the fin isolation structure. In an example, one or more first fin isolation structures are arranged between n-type transistor devices and include a dielectric material structure that imposes tensile stress on the n-type transistor devices, and one or more second fin isolation structures are arranged between p-type transistor devices and include a dielectric material structure that imposes compressive stress on the p-type transistor devices.

### BACKGROUND

As integrated circuits continue to scale downward in size, a number of challenges arise. For instance, reducing the size of memory and logic cells is becoming increasingly more difficult, as is reducing device spacing at the device layer. As transistors are packed more densely, certain factors such as the material strain on the semiconductor channels can have a significant impact on the device performance. Accordingly, there remain a number of non-trivial challenges with respect to forming semiconductor devices.

### BRIEF DESCRIPTION OF THE DRAWINGS

FIG. 1A-1D are cross-sectional and plan views of semiconductor devices that have gate cuts and fin isolation structures with compositionally different materials to impose compressive or tensile strain, in accordance with an embodiment of the present disclosure.

FIGS. 2A and 2B are cross-sectional and plan views that illustrate a first stage in an example process for forming semiconductor devices that have fin isolation structures with compositionally different materials to impose compressive or tensile stress, in accordance with some embodiments of the present disclosure.

FIGS. 3A and 3B are cross-sectional and plan views that illustrate another stage in the example process for forming semiconductor devices that have fin isolation structures with compositionally different materials to impose compressive or tensile stress, in accordance with some embodiments of the present disclosure.

FIGS. 4A and 4B are cross-sectional and plan views that illustrate another stage in the example process for forming semiconductor devices that have fin isolation structures with compositionally different materials to impose compressive or tensile stress, in accordance with some embodiments of the present disclosure.

FIGS. 5A and 5B are cross-sectional and plan views that illustrate another stage in the example process for forming semiconductor devices that have fin isolation structures with compositionally different materials to impose compressive or tensile stress, in accordance with some embodiments of the present disclosure.

FIGS. 6A and 6B are cross-sectional and plan views that illustrate another stage in the example process for forming semiconductor devices that have fin isolation structures with compositionally different materials to impose compressive or tensile stress, in accordance with some embodiments of the present disclosure.

FIGS. 7A and 7B are cross-sectional and plan views that illustrate another stage in the example process for forming semiconductor devices that have fin isolation structures with compositionally different materials to impose compressive or tensile stress, in accordance with some embodiments of the present disclosure.

FIGS. 8A and 8B are cross-sectional and plan views that illustrate another stage in the example process for forming semiconductor devices that have fin isolation structures with compositionally different materials to impose compressive or tensile stress, in accordance with some embodiments of the present disclosure.

FIGS. 9A and 9B are cross-sectional and plan views that illustrate another stage in the example process for forming semiconductor devices that have fin isolation structures with compositionally different materials to impose compressive or tensile stress, in accordance with some embodiments of the present disclosure.

FIGS. 10A and 10B are cross-sectional and plan views that illustrate another stage in the example process for forming semiconductor devices that have fin isolation structures with compositionally different materials to impose compressive or tensile stress, in accordance with some embodiments of the present disclosure.

FIGS. 11A and 11B are cross-sectional and plan views that illustrate another stage in the example process for forming semiconductor devices that have fin isolation structures with compositionally different materials to impose compressive or tensile stress, in accordance with some embodiments of the present disclosure.

FIGS. 12A and 12B are cross-sectional and plan views that illustrate another stage in the example process for forming semiconductor devices that have fin isolation structures with compositionally different materials to impose compressive or tensile stress, in accordance with some embodiments of the present disclosure.

FIGS. 13A and 13B are cross-sectional and plan views that illustrate another stage in the example process for forming semiconductor devices that have fin isolation structures with compositionally different materials to impose compressive or tensile stress, in accordance with some embodiments of the present disclosure.

FIGS. 14A and 14B are cross-sectional and plan views that illustrate another stage in the example process for forming semiconductor devices that have fin isolation structures with compositionally different materials to impose compressive or tensile stress, in accordance with some embodiments of the present disclosure.

FIG. 15 illustrates a cross-sectional view of stacked semiconductor devices having fin isolation structures with compositionally different materials to impose compressive or tensile stress, in accordance with some embodiments of the present disclosure.

FIG. 16 illustrates a cross-sectional view of a chip package containing one or more semiconductor dies, in accordance with some embodiments of the present disclosure.

FIG. 17 is a flowchart of a fabrication process for semiconductor devices that have fin isolation structures with compositionally different materials to impose compressive or tensile strain, in accordance with an embodiment of the present disclosure.

FIG. 18 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form semiconductor devices that include one or more fin isolation structures. Different ones of the fin isolation structures are configured with diverse materials, relative to other ones of the fin isolation structures. The various materials of the fin isolation structures can be selected, such that they cause or otherwise impose beneficial stress (e.g., tensile or compressive) on the adjacent semiconductor devices to improve performance. The techniques can be used in any number of integrated circuit applications and are particularly useful with respect to device layer transistors, such as finFETs, gate-all-around transistors (e.g., ribbonFETs and nanowire FETs) or forksheet transistors (e.g., nanosheet FETs). In an example, a semiconductor device includes a gate structure around or otherwise on a semiconductor region (also referred to as a channel region). The semiconductor region can be, for example, a fin of semiconductor material that extends from a source region to a drain region, or one or more nanowires or nanoribbons or nanosheets of semiconductor material that extend from a source region to a drain region. The gate structure includes a gate dielectric (e.g., high-k gate dielectric material) and a gate electrode (e.g., conductive material such as workfunction material and/or gate fill metal). The semiconductor region (either as a fin or as one or more nanowires, nanoribbons, or nanosheets) may be interrupted, for example, between two diffusion (e.g., source and/or drain) regions with a fin isolation structure that extends through an entire thickness of the gate structure and the semiconductor region and includes dielectric material to electrically isolate the portions of the semiconductor region on either side of the fin isolation structure. In an example, the fin isolation structure is confined within the gate trench such that it does not extend beyond the walls of the gate trench as defined by gate spacer structures. According to some embodiments, one or more first fin isolation structures are arranged between n-type transistor devices and include a dielectric material structure that imposes a tensile stress on the n-type transistor devices, and one or more second fin isolation structures are arranged between p-type transistor devices and include a dielectric material structure that imposes a compressive stress on the p-type transistor devices. Numerous variations and embodiments will be apparent in light of this disclosure.

### General Overview

As previously noted above, there remain a number of non-trivial challenges with respect to integrated circuit fabrication. In more detail, as devices become smaller and more densely packed, many structures become more challenging to fabricate as critical dimensions (CD) of the structures push the limits of current fabrication technology. The stress on such small and densely packed structures can have a significant impact on the device performance. For example, tensile stress imposed on a semiconductor channel enhances electron mobility and thus can improve the performance of n-type transistor devices that use electron carriers. Similarly, compressive stress imposed on a semiconductor channel enhances hole mobility and thus can improve the performance of p-type transistor devices that use hole carriers. Tensile or compressive stress is often applied based on growth characteristics of the epitaxial source or drain regions or from changing the semiconductor channel material used between n-type and p-type transistor devices. Such approaches add substantial process complexity, which can lead to lower device yield.

Thus, and in accordance with an embodiment of the present disclosure, techniques are provided herein to impose tensile or compressive stress using fin isolation structures on either side of n-type transistor devices or p-type transistor devices. In some embodiments, fin isolation structures provided adjacent to n-type transistor devices include one or more dielectric materials that impose a tensile stress (such as a nitride, for instance, silicon nitride), and fin isolation structures provided adjacent to p-type transistor devices include one or more dielectric materials that impose a compressive stress (such as an oxide, for instance, silicon dioxide). Any other suitable dielectric materials can be used that impose either tensile or compressive stress. In some embodiments, fin isolation structures provided adjacent to n-type transistor devices include an airgap within a central portion of the structure. In some embodiments, the ratio of certain elements in the dielectric materials can be tuned to affect the applied stress. For example, fin isolation structures formed from silicon oxynitride (SiOₓN_{y}) with a higher ratio of nitrogen exhibit a higher tensile stress, while other fin isolation structures with a higher ratio of oxygen exhibit a higher compressive stress. In some embodiments, the fin isolation structures may be formed within a gate trench through a previously-formed gate structure within the gate trench, such that the fin isolation structures do not extend beyond the spacer structures that define the edges of the gate trench. In some embodiments, one or more gate cuts between the n-type transistor devices or p-type transistor devices include one or more dielectric materials that impose a tensile stress. The gate cuts may extend in the first direction across portions of the gate structure (e.g., extending perpendicular to the gate structure) and through an entire thickness of the gate structure. In some embodiments, the gate cuts include silicon nitride around an airgap to impose a tensile stress on the n-type transistor devices or p-type transistor devices. According to some embodiments, the fin isolation structures impose its stress on the semiconductor devices along a first direction while the gate cuts impose its stress on the semiconductor devices along a second direction different from the first direction (e.g., orthogonal to the first direction).

According to an embodiment, an integrated circuit includes a first semiconductor device region extending from a first source or drain region in a first direction, a second semiconductor region extending from a second source or drain region in the first direction, a first gate structure extending in a second direction over the first semiconductor region, a second gate structure extending in the second direction over the second semiconductor region, a first dielectric structure extending in the second direction adjacent to the first source or drain region, and a second dielectric structure extending in the second direction adjacent to the second source or drain region. The first dielectric structure exerts a compressive stress on the first semiconductor region and the second dielectric structure exerts a tensile stress on the second semiconductor region.

According to another embodiment, an electronic device includes a chip package having one or more dies. At least one of the one or more dies includes a first semiconductor device having a first semiconductor region extending from a first source or drain region to a second source or drain region in a first direction and a first gate structure extending over the first semiconductor region in a second direction substantially orthogonal to the first direction, a second semiconductor device having a second semiconductor region extending from a third source or drain region to a fourth source or drain region in the first direction and a second gate structure extending over the second semiconductor region in the second direction, a first dielectric structure adjacent to the first source or drain region, and a second dielectric structure adjacent to the third source or drain region and colinearly aligned with the first dielectric structure. The first dielectric structure exerts a compressive stress on the first semiconductor region and the second dielectric structure exerts a tensile stress on the second semiconductor region.

According to another embodiment, an integrated circuit includes a first semiconductor region extending from a first source or drain region to a second source or drain region in a first direction, a second semiconductor region extending from a third source or drain region to a fourth source or drain region in the first direction, a first gate structure extending over the first semiconductor region in a second direction, a second gate structure extending over the second semiconductor region in the second direction, a first dielectric structure extending in the second direction adjacent to the first source or drain region, a second dielectric structure extending in the second direction adjacent to the second source or drain region, a third dielectric structure extending in the second direction adjacent to the third source or drain region, and a fourth dielectric structure extending in the second direction adjacent to the fourth source or drain region. The first and third dielectric structures have different material compositions and are colinear with one another, and the second and fourth dielectric structures have different material compositions and are colinear with one another.

According to another embodiment, a method of forming an integrated circuit includes forming first and second adjacent fins comprising semiconductor material, the fins extending above a substrate and each extending parallel to one another in a first direction; forming a first sacrificial gate and a second sacrificial gate each extending in a second direction over the semiconductor material of the first and second adjacent fins; forming spacer structures on sidewalls of the first and second sacrificial gates; etching through exposed portions of the first and second fins not protected by the first and second sacrificial gates and spacer structures; forming source or drain regions at exposed ends of the first and second fins; replacing the first sacrificial gate with a first gate structure and the second sacrificial gate with a second gate structure; removing a first portion of the second gate structure and any portion of the first fin that had been covered by the first portion of the second gate structure to form a first fin cut trench; forming a first dielectric structure in the first fin cut trench that is aligned with the first fin along the first direction; removing a second portion of the second gate structure and any portion of the second fin that had been covered by the second portion of the second gate structure to form a second fin cut trench; and forming a second dielectric structure in the second fin cut trench that is aligned with the second fin along the first direction. The second dielectric structure has a different material composition compared to the first dielectric structure.

The techniques can be used with any type of non-planar transistors, including finFETs (sometimes called tri-gate transistors), nanowire and nanoribbon transistors (sometimes called gate-all-around transistors), or forksheet transistors, to name a few examples. The source and drain regions can be, for example, epitaxial regions that are deposited during an etch-and-replace source/drain forming process, or implantation-doped portions of substrate. The dopant-type in the source and drain regions will depend on the polarity of the corresponding transistor. The gate structure can be implemented with a gate-last process (sometimes called a replacement metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may be used to detect the presence of fin isolation structures having compositionally different dielectric materials. For example, one or more fin isolation structures may include silicon nitride (or other tensile strain inducing nitride or material), or airgaps while one or more other fin isolation structures may include silicon dioxide (or other compressive strain inducing oxide or material). Numerous configurations and variations will be apparent in light of this disclosure.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally or otherwise meaningfully provided at a different concentration in one material relative to the other material (e.g., SiGe having 70 atomic percent germanium is compositionally different than from SiGe having 25 atomic percent germanium). A trivial or otherwise negligible difference in concentration (e.g., a few atomic percent or less, such as might result from one or more real world limitations with respect to a given deposition process) is distinct from an intentional or meaningful difference, in that such a trivial or negligible difference provides little or no intended benefit to circuit performance or manufacturing process. In addition to such chemical composition diversity, the materials may also have distinct dopants (e.g., gallium and magnesium) or the same dopants but at differing concentrations. In still other embodiments, compositionally different or distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

### Architecture

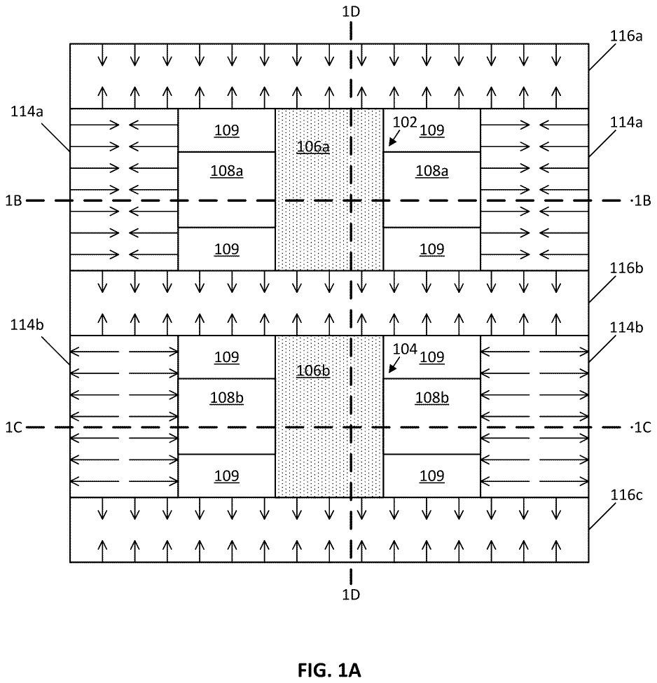

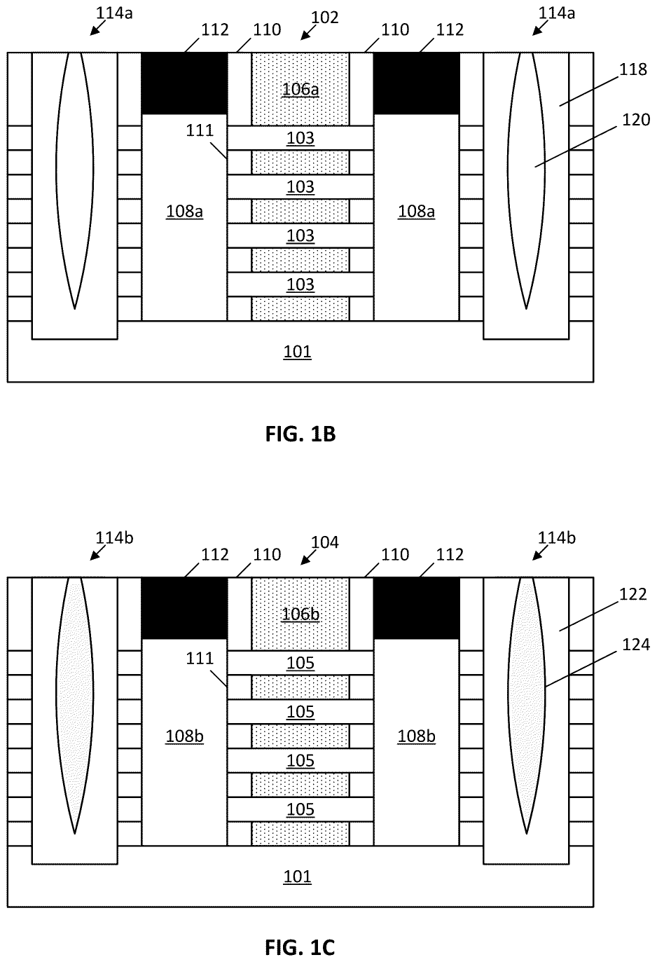

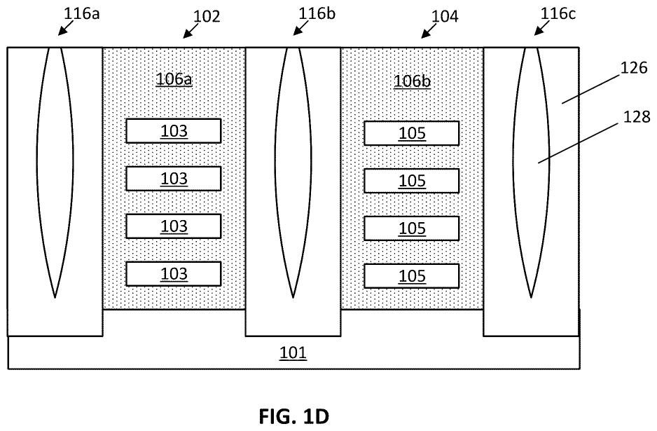

FIG. 1A is a plan layout view of a portion of an integrated circuit that includes fin isolation structures with different material compositions, according to some embodiments. In some examples, the illustrated portion of the integrated circuit may represent a standard unit cell. As shown, the integrated circuit includes a first semiconductor device 102 and a second semiconductor device 104. Each of semiconductor devices 102 and 104 may be, for example, non-planar metal oxide semiconductor (MOS) transistors, such as tri-gate (e.g., finFET) or gate-all-around (GAA) transistors, although other transistor topologies and types could also benefit from the techniques and structures provided herein. The illustrated example embodiments herein use the GAA structure. Semiconductor devices 102 and 104 represent a portion of an integrated circuit that may contain any number of similar semiconductor devices. According to some embodiments, each of first semiconductor device 102 and a second semiconductor device 104 has a semiconductor region extending along a first direction between corresponding source or drain regions. A first gate structure 106a extends along a second direction over the semiconductor region of first semiconductor device 102, and a second gate structure 106b extends along the second direction over the semiconductor region of second semiconductor device 104. FIG. 1B represents a cross-section view taken through semiconductor device 102 across the 1B-1B dashed line, FIG. 1C represents a cross-section view taken through semiconductor device 104 across the 1C-1C dashed line, and FIG. 1D represents a cross-section view taken through both semiconductor devices 102 and 104 along the 1D-1D dashed line.

The semiconductor material used in each of the semiconductor devices may be formed from or on a semiconductor substrate. According to some embodiments, the substrate is removed following the completion of all topside processing and is replaced with a base dielectric structure 101 as seen in the cross-sections of FIG. 1B-1D. Base dielectric structure 101 may represent any number of dielectric layers and/or materials. In some examples, base dielectric structure 101 includes one or more layers of silicon dioxide.

The one or more semiconductor regions of the devices may include fins that can be, for example, native to the substrate (formed from the substrate itself), such as silicon fins etched from a bulk silicon substrate. Alternatively, the fins can be formed of material deposited onto the substrate. In one such example case, a blanket layer of SiGe can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons and nanosheets during a gate forming process where one type of the alternating layers is selectively etched away so as to liberate the other type of alternating layers within the channel region, so that a gate-all-around process or a forksheet gate process can then be carried out. Again, the alternating layers can be blanket deposited and then etched into fins or deposited into fin-shaped trenches, in some examples.

Each semiconductor device 102/104 includes one or more semiconductor regions (also called channel regions), such as one or more nanoribbons 103 of first semiconductor device 102 extending between epitaxial n-type source or drain regions 108a in the first direction and one or more nanoribbons 105 of second semiconductor device 104 extending between epitaxial p-type source or drain regions 108b in the first direction. First gate structure 106a extends over nanoribbons 103 of first semiconductor device 102 in the second direction to form the transistor gate of first semiconductor device 102, and second gate structure 106b extend over nanoribbons 105 of second semiconductor device 104 in the second direction to form the transistor gate of second semiconductor device 104.

Any of source or drain regions 108a/108b may act as either a source region or a drain region, depending on the application and dopant profile. Any semiconductor materials suitable for source and drain regions can be used (e.g., group IV and group III-V semiconductor materials) for any of the illustrated source or drains regions 108a/108b. In any such cases, the composition and doping of source or drain regions 108a and 108b may be the same or different, depending on the polarity of the transistors. In an example, semiconductor device 102 is a n-channel device having a concentration of n-type dopants in the associated source or drain regions 108a, and second semiconductor device 104 is a p-channel device having a concentration of p-type dopants in the associated source or drain regions 108b. Example p-type dopants include boron and example n-type dopants include phosphorous or arsenic. Any number of source and drain configurations and materials can be used. In some examples, first source or drain regions 108a include silicon doped with phosphorous and second source or drain regions 108b include silicon germanium doped with boron. According to some embodiments, a dielectric fill 109 is present along the sides and/or top surfaces of source or drain regions 108a/108b. In some examples, dielectric fill 109 substantially fills any remaining space within the source/drain trenches that extend along the second direction. Dielectric fill 109 may be any suitable dielectric material, such as silicon dioxide.

The gate structures 106a/106b may each include a gate electrode that is made up of a conductive fill and one or more metal workfunction layers, according to some embodiments. The gate structures 106a/106b also include a gate dielectric that may represent any number of dielectric layers. The conductive fill may include any sufficiently conductive material such as a metal, metal alloy, or doped polysilicon. In some examples, the conductive fill includes tungsten (W), although other metals or conductive materials may be used, such as aluminum (Al), molybdenum (Mo), ruthenium (Ru), cobalt (Co), or doped polysilicon. In some embodiments, first semiconductor device 102 is a n-channel device having gate structure 106a with one or more workfunction layers of titanium aluminum carbide. Other metal workfunction layers of n-channel devices can include tantalum nitride (TaN). In some embodiments, second semiconductor device 104 is a p-channel device having gate structure 106b with one or more workfunction layers of tungsten. Other metal workfunction layers of p-channel devices can include tantalum nitride (TaN) and titanium nitride (TiN).

The gate dielectric of each gate structure 106a/106b may include any suitable gate dielectric material(s). In some embodiments, the gate dielectric includes a layer of native oxide material (e.g., silicon dioxide germanium dioxide, or SiGe oxide) on nanoribbons 103/105, and a layer of high-k dielectric material (e.g., hafnium oxide or aluminum oxide) on the native oxide. According to some embodiments, spacer structures 110 and inner spacers 111 are present along the sidewalls of gate structures 106a/106b. Spacer structures 110 and inner spacers 111 may be any suitable dielectric material, such as silicon nitride, and provide separation between a given gate structure 106a/106b and the adjacent source or drain region 108a/108b. Inner spacers 111 may separate adjacent nanoribbons 103/105 from one another along a third direction (e.g., a vertical direction).

According to some embodiments, topside contacts 112 are formed on the top surfaces of any of the source or drain regions 108a/108b. Topside contacts 112 may include any suitable metal layer, such as a layer containing any of tungsten, ruthenium, molybdenum, or cobalt.

According to some embodiments, first fin isolation structures 114a are present on either side of first semiconductor device 102 along the first direction and second fin isolation structures 114b are present on either side of second semiconductor device 104 along the first direction. First fin isolation structures 114a may be colinearly aligned along the second direction with second fin isolation structures 114b, as seen in FIG. 1A. Each of first fin isolation structures 114a and second fin isolation structures 114b may be a dielectric structure that includes one or more dielectric materials and/or airgaps to impose either a tensile or compressive stress on the adjacent devices along the first direction. In some embodiments, gate cuts 116a, 116b, and 116c extend along the first direction at least across gate structures 106a and 106b. Each of gate cuts 116a, 116b, and 116c may be a dielectric structure that includes one or more dielectric materials and/or airgaps to impose tensile stress on the adjacent devices along the second direction.

In the illustrated plan view of FIG. 1A, first fin isolation structures 114a impose a tensile stress along the first direction on first semiconductor device 102, as identified by the inwardly-pointing arrows. FIG. 1B illustrates an example of first fin isolation structures 114a that includes a first dielectric material 118 and an airgap 120 to impose a tensile stress along the first direction on nanoribbons 103. According to some embodiments, first dielectric material 118 includes silicon nitride, silicon oxynitride, or generally any dielectric material that imposes a tensile stress on adjacent structures along the first direction. First dielectric material 118 may be formed along the surfaces of a fin trench using a suitable deposition technique, such as chemical vapor deposition (CVD) or physical vapor deposition (PVD). Due to the high aspect ratio of the fin trench, the top of first dielectric material 118 may begin to pinch closed leaving airgap 120 within a central portion of first fin isolation structures 114a. The presence of airgap 120 may contribute even more tensile stress on the adjacent structures along the first direction. It should be noted that the term airgap may refer to any space devoid of solid material, where the gases in the space can include those used during the CVD or PVD process, such as argon or nitrogen. Additionally, airgap 120 may be at a vacuum pressure. Although not shown in this cross-section, one or more dielectric layers may be formed over the top of first fin isolation structures 114a, which may be used to seal the top of airgap 120. In other examples, first dielectric material 118 may be deposited until it pinches together at the top of the structure, thus sealing airgap 120 in the middle. In some other embodiments, airgap 120 is instead filled with another dielectric material that also imposes a tensile stress on the adjacent structures along the first direction.

In the illustrated plan view of FIG. 1A, second fin isolation structures 114b impose a compressive stress along the first direction on first semiconductor device 102, as identified by the outwardly-pointing arrows. FIG. 1C illustrates an example of second fin isolation structures 114b that includes a second dielectric material 122 and a third dielectric material 124 to impose a compressive stress along the first direction on nanoribbons 105. According to some embodiments, second dielectric material 122 includes silicon dioxide, silicon oxynitride, or generally any dielectric material that imposes a compressive stress on adjacent structures along the first direction. Second dielectric material 122 may be formed along the surfaces of a fin trench using a suitable deposition technique, such as CVD or PVD. Following the formation of second dielectric material 122, third dielectric material 124 may be formed within any remaining volume of the fin trench to complete the formation of second fin isolation structures 114b. Third dielectric material 124 may be a compressive silicon dioxide or a compressive form of silicon nitride.

In some embodiments, each of first fin isolation structures 114a and second fin isolation structures 114b only includes a single dielectric material. For example, second fin isolation structures 114b may only include silicon dioxide to impose compressive stress, and first fin isolation structures 114a may only include silicon nitride to impose tensile stress. In some embodiments, second fin isolation structures 114b includes at least 99%, 95%, or 90% silicon dioxide, and first fin isolation structures 114a includes at least 99%, 95%, or 90% silicon nitride. Other examples may include other compositionally different dielectrics that can impose one of tensile or compressive stress (any combination of oxide, nitride, carbide, oxynitride, oxycarbide, carbonitride, or oxycarbonitride dielectric materials). According to some embodiments, each of first fin isolation structures 114a and second fin isolation structures 114b include a dielectric material having a different elemental ratio to affect the imposed stress. For example, second fin isolation structures 114b may include silicon oxynitride having a higher ratio of oxygen compared to nitrogen to impose a compressive strain, and first fin isolation structures 114a may include silicon oxynitride having a higher ratio of nitrogen compared to oxygen to impose a tensile strain.

In the illustrated plan view of FIG. 1A, gate cuts 116a, 116b, and 116c impose a tensile stress along the second direction on first semiconductor device 102 and second semiconductor device 104, as identified by the inwardly-pointing arrows. FIG. 1D illustrates an example of gate cuts 116a, 116b, and 116c that includes a fourth dielectric material 126 and an airgap 128 to impose a tensile stress along the second direction on nanoribbons 103 and 105. Each of gate cuts 116a, 116b, and 116c may extend though at least an entire thickness of gate structures 106a/106b. According to some embodiments, gate cuts 116a, 116b, and 116c may have similar structures to first fin isolation structures 114a. For example, fourth dielectric material 126 can include silicon nitride, silicon oxynitride, or generally any dielectric material that imposes a tensile stress on adjacent structures along the second direction, and airgap 128 may remain within a central portion of gate cuts 116a, 116b, and 116c following the formation of fourth dielectric material 126. The presence of airgap 128 may contribute even more tensile stress on the adjacent structures along the second direction. In some embodiments, gate cut 116b is omitted such that gate structures 116a/116b are combined into a single gate structure that extends in the second direction over both nanoribbons 103 and 105. Furthermore, without gate cut 116b, first fin isolation structures 114a may directly abut second fin isolation structures 114b along the second direction.

### Fabrication Methodology

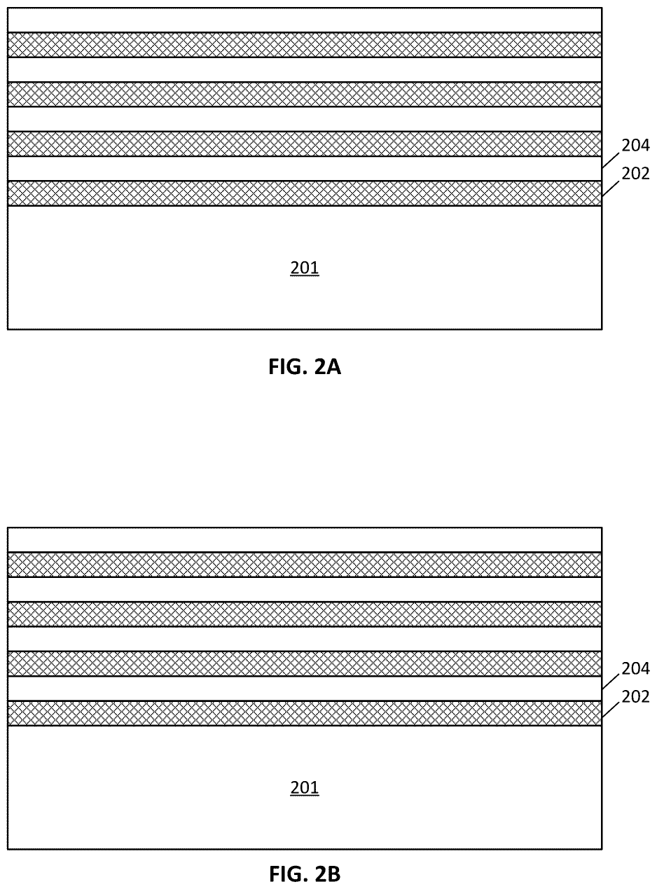

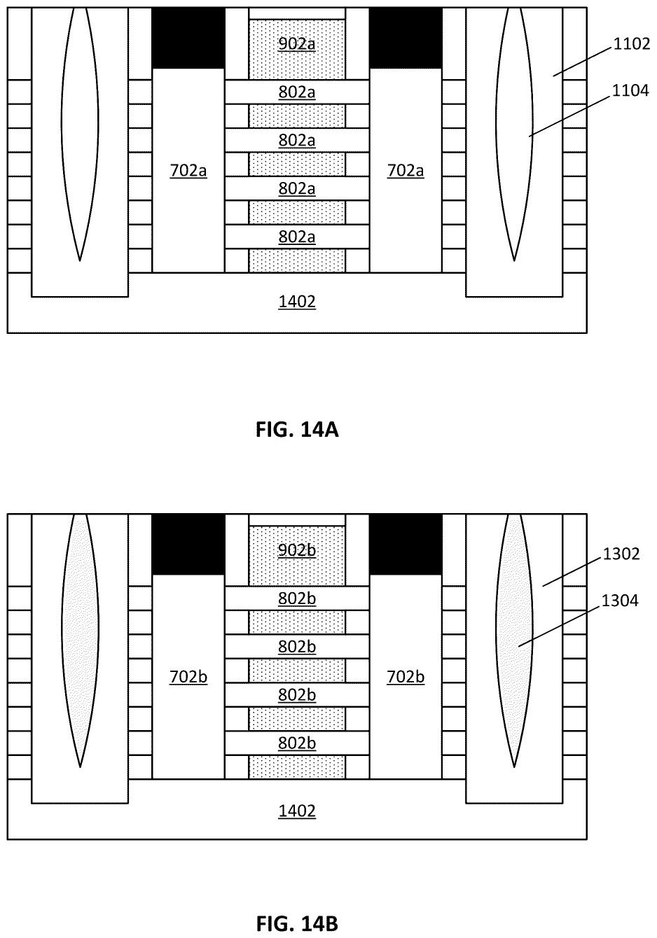

FIG. 2A-14A and 2B-14B include cross-sectional views that collectively illustrate an example process for forming an integrated circuit having semiconductor devices adjacent to fin isolation structures having different dielectric material compositions to impose tensile or compressive stress, in accordance with an embodiment of the present disclosure. FIG. 2A-14A represent a similar cross-sectional view as that of FIG. 1B across a n-channel semiconductor device, while FIG. 2B-14B represent a similar cross-sectional view as that of FIG. 1C across a p-channel semiconductor device. Each set of figures sharing the same letter shows an example structure that results from the process flow up to that point in time, so the depicted structure evolves as the process flow continues, culminating in the structure shown in FIGS. 14A and 14B, which is similar to the structure shown in FIGS. 1B and 1C. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but other materials and process parameters may be used as well, as will be appreciated in light of this disclosure.

FIGS. 2A and 2B each illustrates a cross-sectional view taken through a substrate 201 having a series of material layers formed over substrate 201, according to an embodiment of the present disclosure. Alternating material layers may be deposited over substrate 201 including sacrificial layers 202 alternating with semiconductor layers 204. The alternating layers are used to form GAA transistor structures. Any number of alternating sacrificial layers 202 and semiconductor layers 204 may be deposited over substrate 201.

Substrate 201 can be, for example, a bulk substrate including group IV semiconductor material (such as silicon, germanium, or SiGe), group III-V semiconductor material (such as gallium arsenide, indium gallium arsenide, or indium phosphide), and/or any other suitable material upon which transistors can be formed. Alternatively, substrate 201 can be a semiconductor-on-insulator substrate having a desired semiconductor layer over a buried insulator layer (e.g., silicon over silicon dioxide). Alternatively, substrate 201 can be a multilayer substrate or superlattice suitable for forming nanowires or nanoribbons (e.g., alternating layers of silicon and SiGe, or alternating layers indium gallium arsenide and indium phosphide). Any number of substrates can be used.

According to some embodiments, semiconductor layers 204 have a different material composition than sacrificial layers 202. In some embodiments, semiconductor layers 204 include a semiconductor material suitable for use as a nanoribbon such as silicon (Si), SiGe, germanium, or III-V materials like indium phosphide (InP) or gallium arsenide (GaAs). Sacrificial layers 202 include a material that can be selectively removed relative to semiconductor layers 204. In some examples, for instance, semiconductor layers 204 are silicon and sacrificial layers 202 are SiGe, or vice-versa. In some other examples where SiGe is used in each of semiconductor layers 204 and in sacrificial layers 202, the germanium concentration is different between semiconductor layers 204 and sacrificial layers 202, so as to allow for etch selectivity. For example, semiconductor layers 204 may include a higher germanium content compared to sacrificial layers 202.

While dimensions can vary from one example embodiment to the next, the thickness of each semiconductor layer 204 may be between about 5 nm and about 20 nm, in some examples. In some embodiments, the thickness of each semiconductor layer 204 is substantially the same (e.g., within 1-2 nm). The thickness of each of sacrificial layers 202 may be about the same as the thickness of each semiconductor layer 204 (e.g., about 5-20 nm). Each of semiconductor layers 204 and sacrificial layers 202 may be deposited using any material deposition technique, such as chemical vapor deposition (CVD), plasma-enhanced chemical vapor deposition (PECVD), physical vapor deposition (PVD), or atomic layer deposition (ALD), or epitaxial growth.

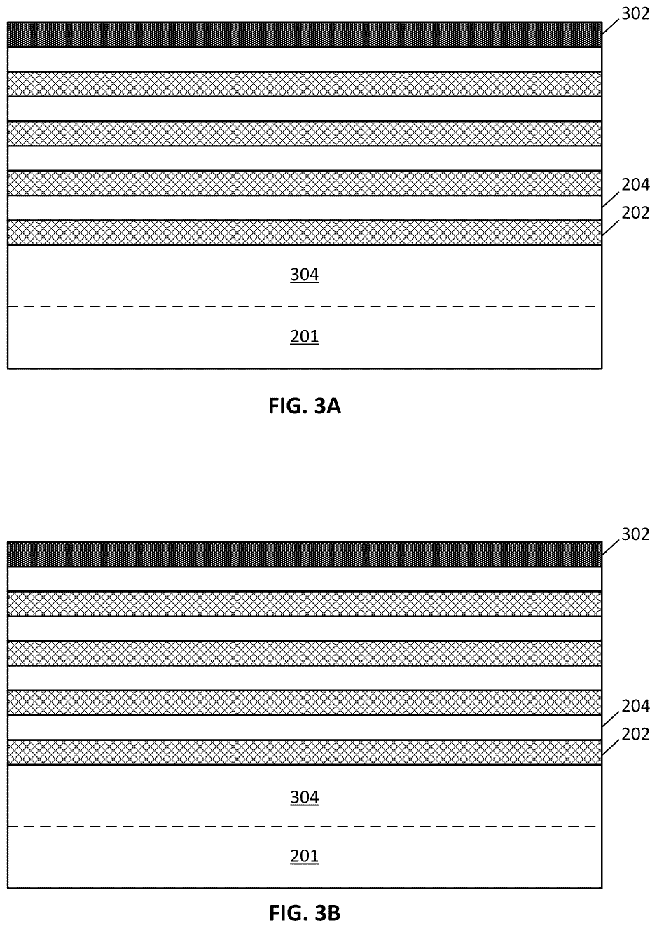

FIGS. 3A and 3B depict the cross-section views of the structure shown in FIGS. 2A and 2B, respectively, following the formation of a cap layer 302 and the subsequent formation of fins beneath cap layer 302, according to an embodiment. Cap layer 302 may be any suitable hard mask material such as a carbon hard mask (CHM) or silicon nitride. Cap layer 302 is patterned into rows to form corresponding rows of fins from the alternating layer stack of sacrificial layers 202 and semiconductor layers 204. Cap layer 302 extends along the top of each fin in a first direction. In some embodiments, FIGS. 3A and 3B illustrate portions of different parallel fins (e.g., under different parallel strips of cap layer 302).

According to some embodiments, an anisotropic etching process through the layer stack continues into at least a portion of substrate 201. Portions of substrate 201 beneath the fins are not etched and yield subfin regions 304. The etched portions of substrate 201 that are not under the fins may be filled with a dielectric fill that acts as shallow trench isolation (STI) between adjacent fins. The dielectric fill is not shown in these cross-sections as it extends in the first direction along the sides of subfin regions 304 that are into and out of the page. The dielectric fill may be any suitable dielectric material such as silicon dioxide. The subfin regions 304 represent remaining portions of substrate 201 flanked by the dielectric fill, according to some embodiments.

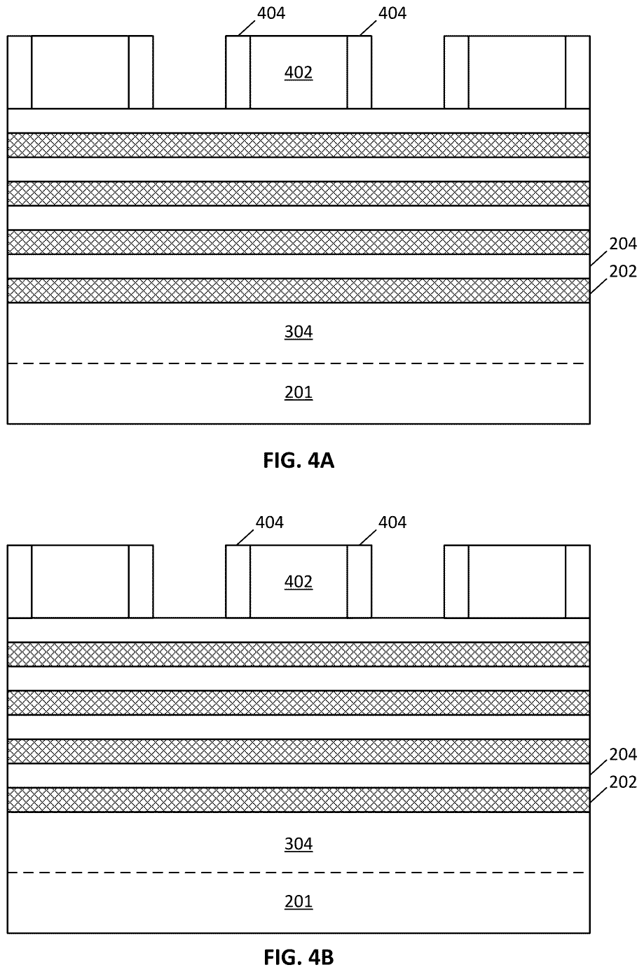

FIGS. 4A and 4B depict cross-section views of the structures shown in FIGS. 3A and 3B following the formation of sacrificial gates 402 and spacer structures 404, according to some embodiments. A gate masking layer may first be patterned in strips that extend orthogonally across each of the fins (e.g., in a second direction) in order to form corresponding sacrificial gates 402 in strips beneath the gate masking layers. Afterwards, the gate masking layers may be removed or may remain as a cap layer above each sacrificial gate 402. According to some embodiments, the sacrificial gate material is removed in all areas not protected by the gate masking layers. Sacrificial gate 402 may be any suitable material that can be selectively removed without damaging the semiconductor material of the fins. In some examples, sacrificial gate 402 includes polysilicon.

According to some embodiments, spacer structures 404 are formed along the sidewalls of sacrificial gates 402. Spacer structures 404 may be conformally deposited (e.g., CVD or ALD) and then etched back or otherwise removed (e.g., via anisotropic or directional etch) from horizontal surfaces, such that spacer structures 404 remain mostly only on sidewalls of any exposed structures. The width of spacer structures 404 (along the first direction) may vary from one example to the next, but in some cases is in the range of 3 nm to 20 nm. According to some embodiments, spacer structures 404 may be any suitable dielectric material, such as silicon nitride, silicon carbon nitride, or silicon oxycarbonitride. In one such embodiment, spacer structures 404 comprise a nitride and the dielectric fill adjacent to subfin regions 304 comprises an oxide, so as to provide a degree of etch selectivity during final gate processing.

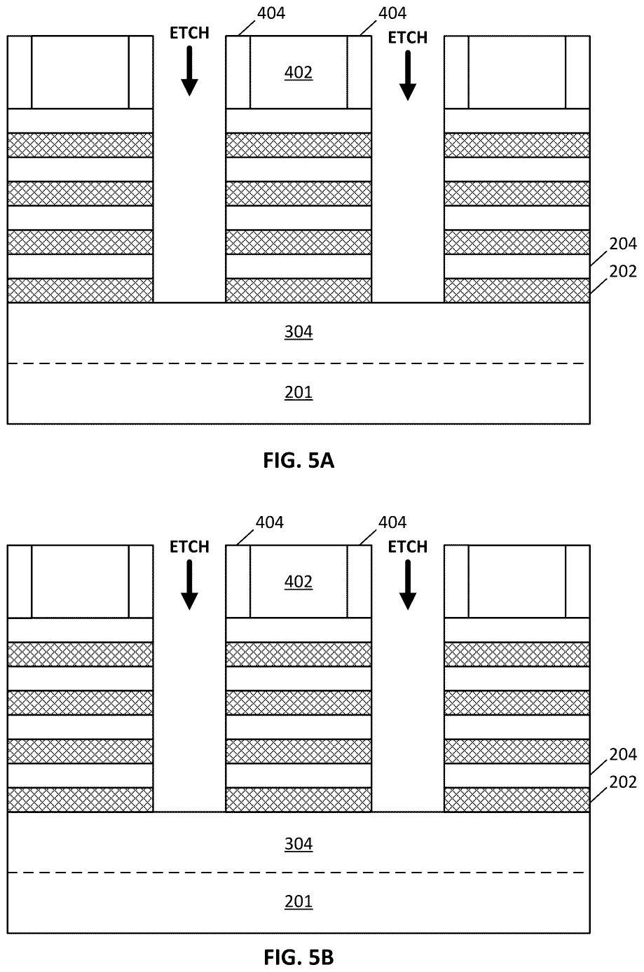

FIGS. 5A and 5B depict cross-section views of the structures shown in FIGS. 4A and 4B following the removal of exposed portions of the fins not protected by sacrificial gates 402 and spacer structures 404, according to some embodiments. The exposed fin portions may be removed using any anisotropic etching process, such as reactive ion etching (RIE) or other directional etch process. The removal of the exposed fin portions creates source or drain trenches that alternate with gate trenches (currently filled with sacrificial gates 402) along the first direction, according to some embodiments. In some embodiments, at least a portion of subfin regions 304 is also removed such that a top surface of subfin regions 304 is recessed below a top surface of the adjacent dielectric fill.

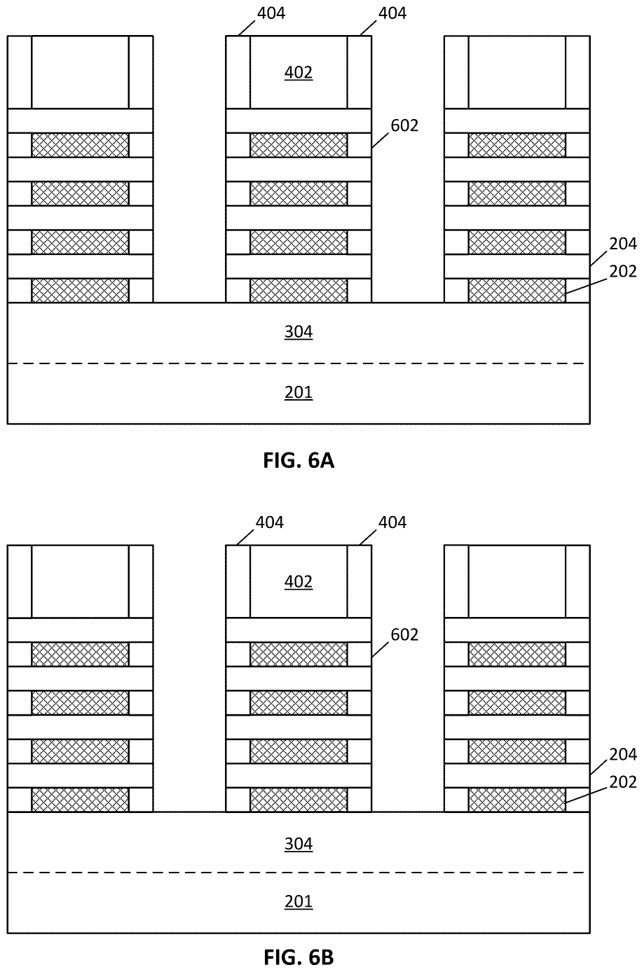

FIGS. 6A and 6B depict cross-section views of the structures shown in FIGS. 5A and 5B following the removal of portions of sacrificial layers 202 and formation of inner spacers 602 within the lateral recesses, according to an embodiment of the present disclosure. An isotropic etching process may be used to selectively recess the exposed ends of each sacrificial layer 202 (e.g., while etching comparatively little of semiconductor layers 204).

Inner spacers 602 may have a material composition that is similar to or the exact same as spacer structures 404. Accordingly, inner spacers 602 may be any suitable dielectric material that exhibits high etch selectively to semiconductor materials such as silicon and/or silicon germanium. Inner spacers 602 may be, for example, conformally deposited over the sides of the fin structure using a conformal deposition process like CVD or atomic layer deposition (ALD) and then etched back using an isotropic etching process to expose the ends of semiconductor layers 204. According to some embodiments, inner spacers 602 have a similar width (e.g., along the first direction) to spacer structures 404.

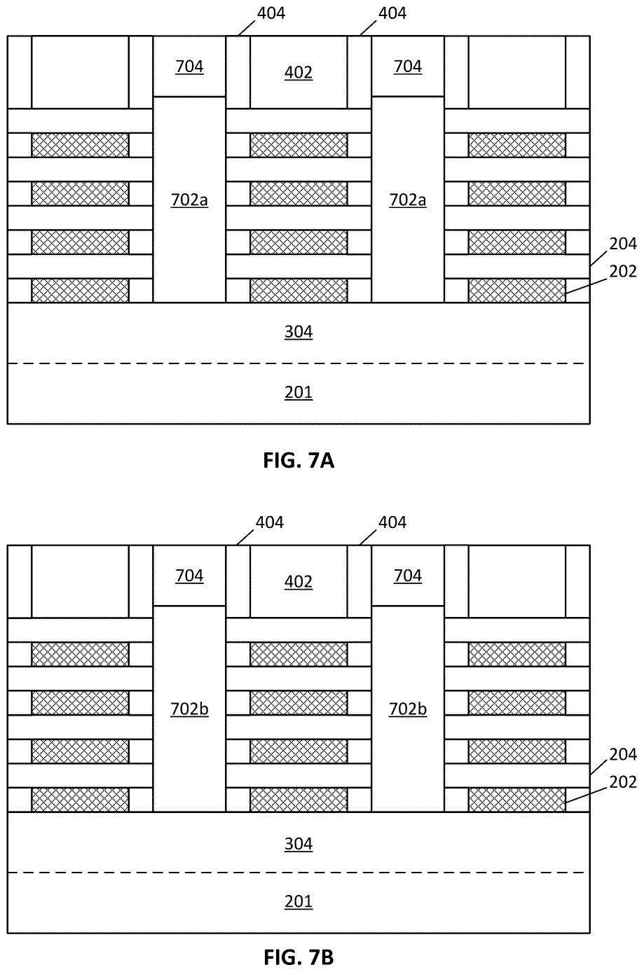

FIGS. 7A and 7B depict cross-section views of the structure shown in FIGS. 6A and 6B, respectively, following the formation of first source or drain regions 702a and second source or drain regions 702b within the source/drain trenches, according to some embodiments. Source or drain regions 702a/702b may be formed in the areas that had been previously occupied by the exposed fins between spacer structures 404. According to some embodiments, source or drain regions 702a/702b are epitaxially grown from the exposed semiconductor material at the ends of semiconductor layers 204. In some example embodiments, first source or drain regions 702a are n-type source or drain regions (e.g., epitaxial silicon with n-type dopants, such as phosphorous) and second source or drain regions 702b are p-type source or drain regions (e.g., epitaxial silicon germanium with p-type dopants, such as boron).

According to some embodiments, a dielectric fill 704 is provided over source or drain regions 702a/702b. In some examples, dielectric fill 704 occupies a remaining volume within the source/drain trenches around and over portions of source or drain regions 702a/702b. Dielectric fill 704 may be any suitable dielectric material, such as silicon dioxide. In some examples, dielectric fill 704 extends up to and planar with a top surface of spacer structures 404 (e.g., following a polishing procedure).

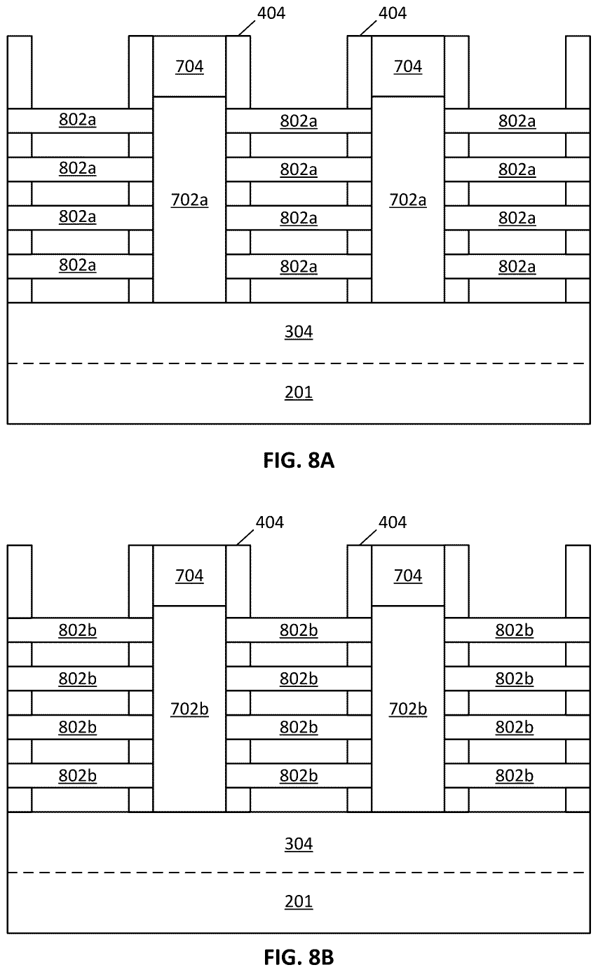

FIGS. 8A and 8B depict cross-section views of the structure shown in FIGS. 7A and 7B, respectively, following the removal of sacrificial gates 402 and sacrificial layers 202, according to some embodiments. In examples where gate masking layers are still present, they may be removed at this time. Once sacrificial gates 402 are removed, the remaining fin portions extending between spacer structures 404 are exposed.

In the example where the fins include alternating sacrificial layers 202 and semiconductor layers 204, sacrificial layers 202 are selectively removed to leave behind nanoribbons 802a extending between first source or drain regions 702a and nanoribbons 802b extending between second source or drain regions 702b. Each vertical set of nanoribbons 802a/802b represents the semiconductor region (also called channel region) of a different semiconductor device. It should be understood that nanoribbons 802a/802b may also be nanowires or nanosheets. Sacrificial gates 402 and sacrificial layers 202 may be removed using the same isotropic etching process or different isotropic etching processes.

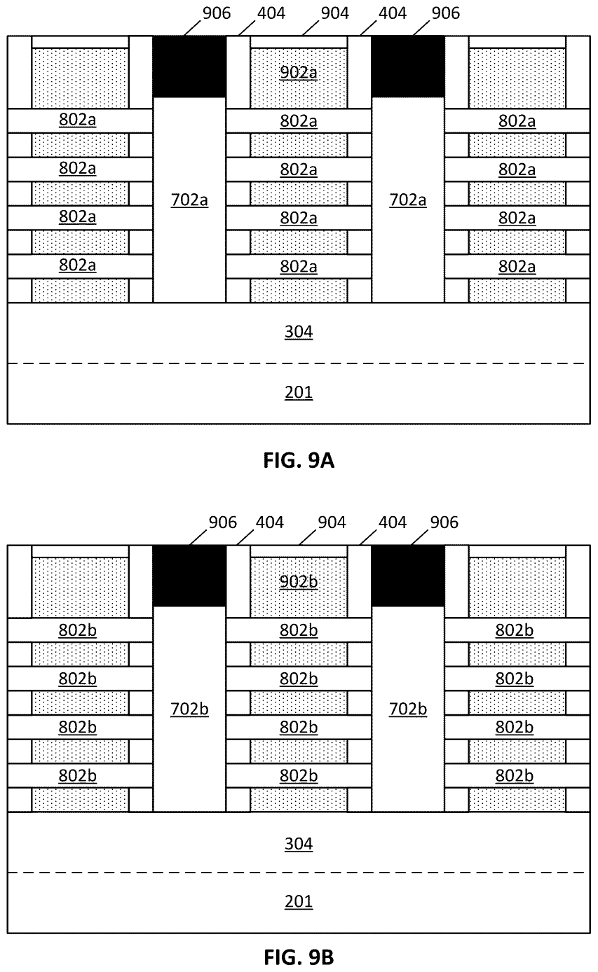

FIGS. 9A and 9B depict cross-section views of the structure shown in FIGS. 8A and 8B, respectively, following the formation of first gate structures 902a around the suspended nanoribbons 802a and second gate structures 902b around the suspended nanoribbons 802b, according to an embodiment of the present disclosure. As noted above, gate structures 902a/902b each include a gate dielectric and a gate electrode.

The gate dielectric may be conformally deposited around nanoribbons 802a/802b using any suitable deposition process, such as ALD. The gate dielectric may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, the gate dielectric is hafnium oxide with a thickness between about 1 nm and about 5 nm. In some embodiments, the gate dielectric may include one or more silicates (e.g., titanium silicate, tungsten silicate, niobium silicate, and silicates of other transition metals). The gate dielectric may be a multilayer structure, in some examples. For instance, the gate dielectric may include a first layer on nanoribbons 802a/802b, and a second layer on the first layer. The first layer can be, for instance, an oxide of the semiconductor layers (e.g., silicon dioxide) and the second layer can be a high-k dielectric material (e.g., hafnium oxide). In some embodiments, an annealing process may be carried out on the gate dielectric to improve its quality when a high-k dielectric material is used. In some embodiments, the high-k material can be nitridized to improve its aging resistance.

The gate electrode may be deposited over the gate dielectric and can be any standard or proprietary conductive material that may include any number of gate cuts. In some embodiments, the gate electrode includes doped polysilicon, a metal, or a metal alloy. Example suitable metals or metal alloys include aluminum, tungsten, cobalt, molybdenum, ruthenium, titanium, tantalum, copper, and carbides and nitrides thereof. The gate electrode may include, for instance, one or more workfunction layers, resistance-reducing layers, and/or barrier layers. In an example, first gate structures 902a include n-type workfunction materials such as, for example, titanium aluminum carbide or tantalum nitride. In an example, second gate structures 902b include p-type workfunction materials such as tungsten.

According to some embodiments, a top portion of the gate electrode may be recessed within the gate trench. The recessed area may be filled with a dielectric material to form a gate cap 904. According to some embodiments, gate cap 904 includes any suitable dielectric material, such as silicon nitride or silicon oxynitride. In some examples, gate cap 904 includes the same dielectric material as spacer structures 404.

According to some embodiments, at least a portion of dielectric fill 704 over source or drain regions 702a/702b is removed and topside conductive contacts 906 are formed on the top surfaces of source or drain regions 702a/702b, according to some embodiments. Dielectric fill 704 may be removed using any suitable isotropic etching process to reveal a top surface of source or drain regions 702a/702b. Topside conductive contacts 906 may be formed at the same time (e.g. during a single deposition process) on top of both first source or drain regions 702a and second source or drain regions 702b, or may be formed using different deposition processes to form topside conductive contacts 906 on first source or drain regions 702a followed by forming topside conductive contacts 906 on second source or drain regions 702b, or vice-versa. Topside conductive contacts 906 may include, for instance, titanium for forming a silicide or germanide material following an anneal, according to some examples. Topside conductive contacts 906 may further include any suitable conductive material, such as aluminum, tungsten, cobalt, molybdenum, ruthenium, tantalum, copper, titanium, and carbides and nitrides thereof. A top surface of topside conductive contacts 906 may be polished using, for example, chemical mechanical polishing (CMP) until it is substantially coplanar with a top surface of gate cap 904 and/or spacer structures 404.

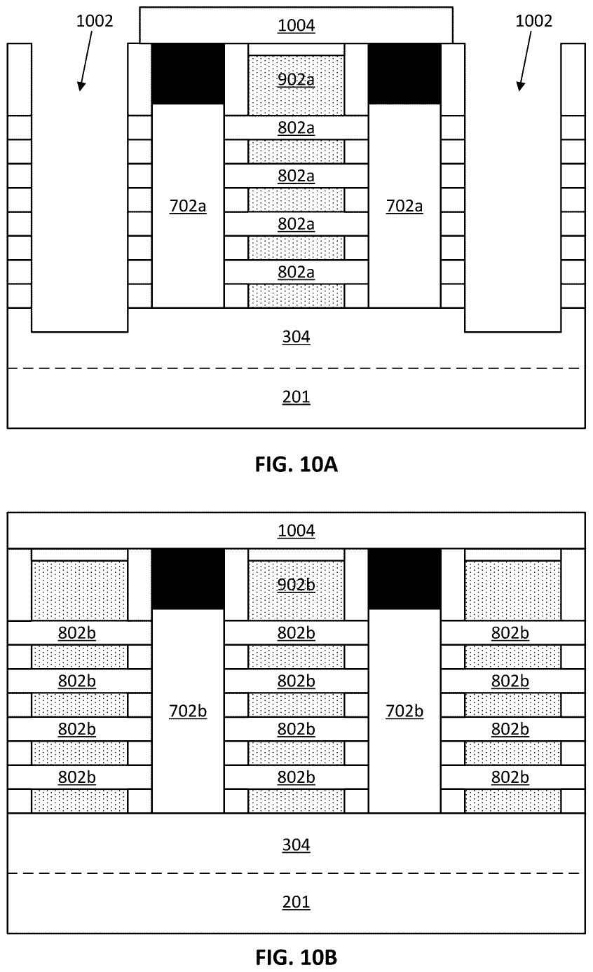

FIGS. 10A and 10B depict cross-section views of the structure shown in FIGS. 9A and 9B, respectively, following the formation of trench recesses 1002, according to some embodiments. A mask structure 1004 may first be deposited across the top of the entire structure and patterned using suitable lithography techniques to remain over the p-channel devices shown in FIG. 10B, while exposing certain n-channel devices as shown in FIG. 10A. An anisotropic etching process (e.g., RIE) may be used to etch trench recesses 1002 through the exposed n-channel devices. According to some embodiments, the etch process removes the exposed gate structures 902a and the corresponding nanoribbons 802a extending through the exposed gate structures 902a. Trench recesses 1002 extend along the second direction (e.g., into and out of the page). In some examples, trench recesses 1002 extend along the second direction between gate cuts that extend along the first direction across gate structures 902a. In some examples, trench recesses 1002 extend along the second direction through any number of devices. According to some embodiments, trench recesses 1002 extend through at least an entire thickness of gate structures 902a and may extend into at least a portion of subfin region 304 or at least a portion of substrate 201. The width of trench recesses 1002 (e.g., along the first direction) may be substantially equal to the entire width of the gate trenches between spacer structures 404.

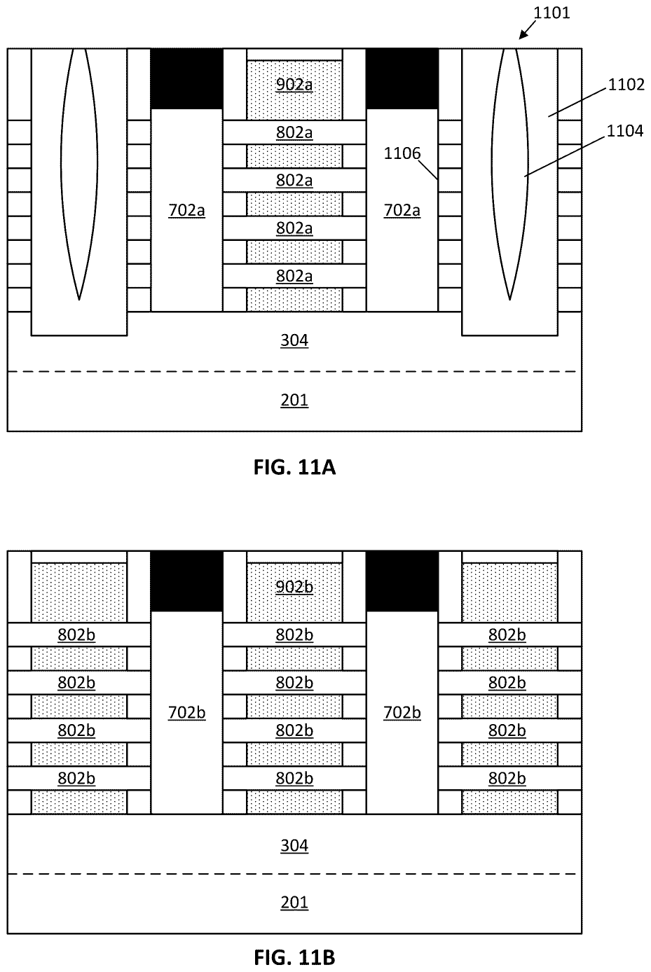

FIGS. 11A and 11B depict cross-section views of the structure shown in FIGS. 9A and 9B, respectively, following the formation of first fin isolation structures 1101 within trench recesses 1002, according to some embodiments. Mask structure 1004 may be removed prior to the formation of first fin isolation structures 1101. First fin isolation structures 1101 may have one or more dielectric materials and/or airgaps that impose a tensile stress on nanoribbons 802a of the adjacent n-channel device. For example, first fin isolation structures 1101 may include a dielectric material 1102 around an airgap 1104. In some embodiments, dielectric material 1102 can be any material that imposes a tensile stress along at least the first direction, such as silicon nitride or silicon oxynitride with a higher concentration of nitrogen compared to oxygen. Other examples for dielectric material 1102 may include other compositionally different dielectrics that can impose tensile stress (any combination of oxide, nitride, carbide, oxynitride, oxycarbide, carbonitride, or oxycarbonitride dielectric materials). In some examples, airgap 1104 is instead filled with a dielectric material that imposes a tensile stress, such as any of the aforementioned materials for dielectric material 1102.

According to some embodiments, dielectric material 1102 may be deposited within trench recesses 1002 using a conformal technique, such as CVD or ALD. Due to the high-aspect ratio of trench recesses 1002, the deposited dielectric material 1102 at the top of the recess may begin to pinch inwards, thus enclosing a region in the central portion of trench recesses 1002. According to some embodiments, no solid material is formed within this central portion, thus forming airgap 1104. It should be noted that dielectric material 1102 may fully pinch together to enclose airgap 1104, or it may pinch inwards at the top without touching, in which case another dielectric layer deposited on the top of the structure completes the enclosure of airgap 1104. As discussed above, airgap 1104 may include one or more gases used during the deposition process (e.g., argon or nitrogen) and may be at vacuum pressure. Accordingly, the presence of airgap 1104 causes first fin isolation structures 1101 to impose a tensile strain on the surrounding semiconductor device components.

According to some embodiments, semiconductor portions 1106 extend along the first direction between first source or drain region 702a and first fin isolation structure 1101. Semiconductor portions 1106 represent portions of nanoribbons 802a that remain behind following the formation of trench recess 1002. Accordingly, semiconductor portions 1106 may be the same semiconductor material as nanoribbons 802a and may be colinear with nanoribbons 802a along the first direction.

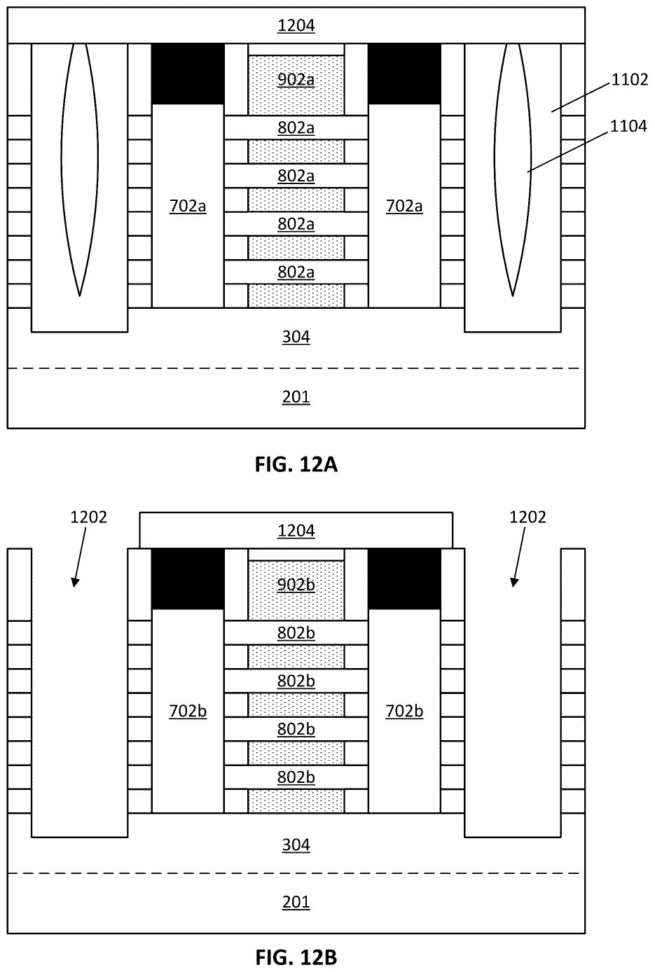

FIGS. 12A and 12B depict cross-section views of the structure shown in FIGS. 11A and 11B, respectively, following the formation of trench recesses 1202, according to some embodiments. A mask structure 1204 may first be deposited across the top of the entire structure and patterned using suitable lithography techniques to remain over the n-channel devices shown in FIG. 12B, while exposing certain p-channel devices as shown in FIG. 12A. An anisotropic etching process (e.g., RIE) may be used to etch trench recesses 1202 through the exposed p-channel devices. According to some embodiments, the etch process removes the exposed gate structures 902b and the corresponding nanoribbons 802b extending through the exposed gate structures 902b. Trench recesses 1202 extend along the second direction (e.g., into and out of the page). In some examples, trench recesses 1202 extend along the second direction between gate cuts that extend along the first direction across gate structures 902b. In some examples, trench recesses 1202 extend along the second direction through any number of devices. According to some embodiments, trench recesses 1202 extend through at least an entire thickness of gate structures 902b and may extend into at least a portion of subfin region 304 or at least a portion of substrate 201. The width of trench recesses 1202 (e.g., along the first direction) may be substantially equal to the entire width of the gate trenches between spacer structures 404. In some examples, trench recesses 1202 are colinearly aligned with first fin isolation structures 1101 along the second direction and may abut first fin isolation structures 1101 or may be separated from first fin isolation structures 1101 by a gate cut.

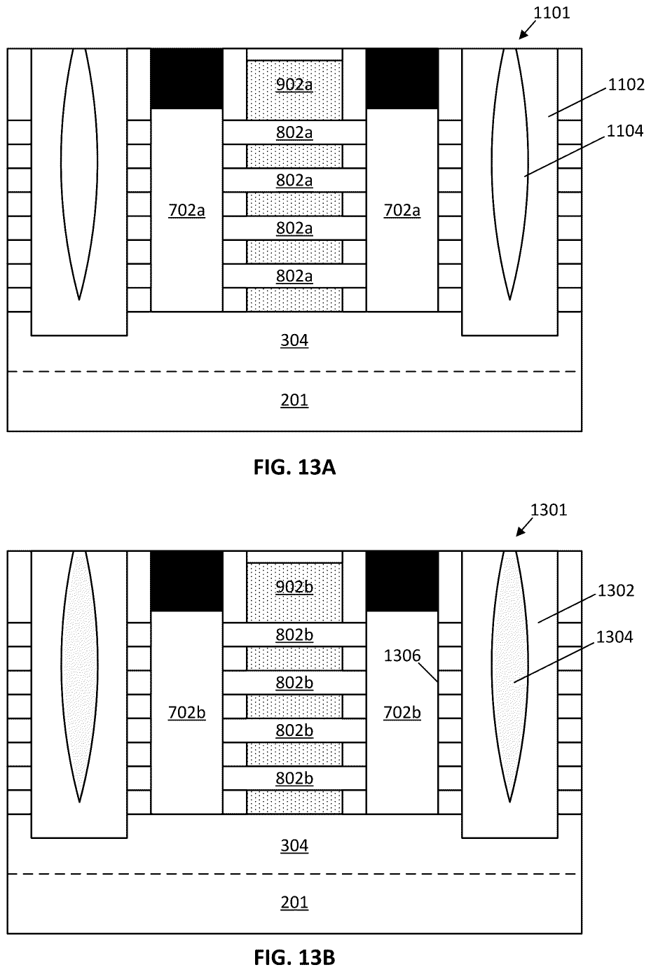

FIGS. 13A and 13B depict cross-section views of the structure shown in FIGS. 12A and 12B, respectively, following the formation of second fin isolation structures 1301 within trench recesses 1202, according to some embodiments. Mask structure 1204 may be removed prior to the formation of second fin isolation structures 1301. Second fin isolation structures 1301 may have one or more dielectric materials that impose a compressive stress on nanoribbons 802b of the adjacent p-channel device. For example, second fin isolation structures 1301 may include a first dielectric material 1302 around a second dielectric material 1304. In some embodiments, each of first dielectric material 1302 and second dielectric material 1304 can be any material that imposes a compressive stress along at least the first direction, such as silicon dioxide or silicon oxynitride with a higher concentration of oxygen compared to nitrogen. Other examples for first dielectric material 1302 and second dielectric material 1304 may include other compositionally different dielectrics that can impose compressive stress (any combination of oxide, nitride, carbide, oxynitride, oxycarbide, carbonitride, or oxycarbonitride dielectric materials).

According to some embodiments, semiconductor portions 1306 extend along the first direction between second source or drain region 702b and second fin isolation structure 1301. Semiconductor portions 1306 represent portions of nanoribbons 802b that remain behind following the formation of trench recess 1202. Accordingly, semiconductor portions 1306 may be the same semiconductor material as nanoribbons 802b and may be colinear with nanoribbons 802b along the first direction.

FIGS. 14A and 14B depict cross-section views of the structure shown in FIGS. 13A and 13B, respectively, following the removal of a backside portion of substrate 201, according to some embodiments. Any number of polishing, grinding, or etching processes (e.g., CMP) may be used to remove the bulk portion of substrate 201. According to some embodiments, substrate 201 is removed until a bottom surface of subfin regions 304 and/or the dielectric layer adjacent to the subfin regions is exposed. According to some embodiments, the exposed subfin regions 304 are removed and replaced with a base dielectric structure 1402. Subfin regions 304 may be removed using a suitable isotropic etching process followed by the backside formation of base dielectric structure 1402. According to some embodiments, base dielectric structure 1402 includes any number of dielectric layers. In some examples, base dielectric structure 1402 includes a layer of silicon dioxide. Base dielectric layer may be polished such that a bottom surface of base dielectric structure 1402 is substantially planar.

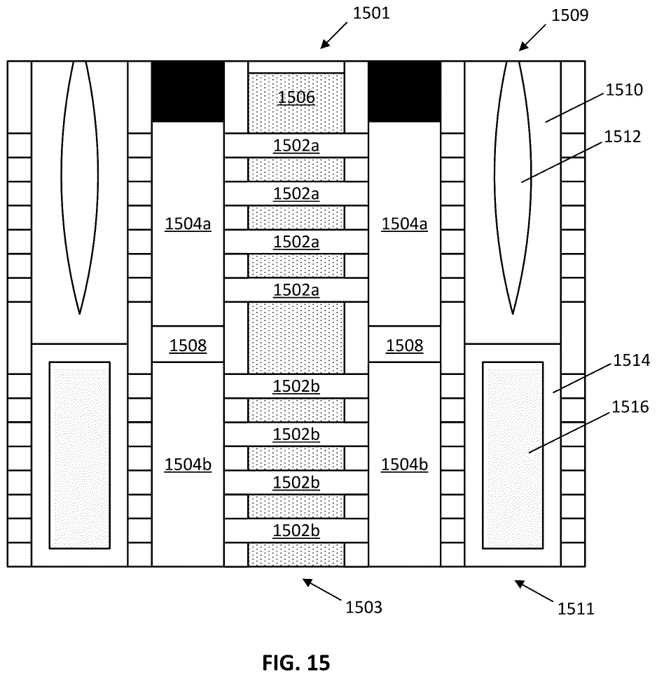

FIG. 15 depicts a cross-section view of an example portion of an integrated circuit that includes stacked semiconductor devices, according to some embodiments. The stacked devices may include a first semiconductor device 1501 over a second semiconductor device 1503. First semiconductor device 1501 includes first nanoribbons 1502a extending in the first direction between n-type source or drain regions 1504a, and second semiconductor device 1503 includes second nanoribbons 1502b extending in the first direction between p-type source or drain regions 1504b. In some examples, first semiconductor device 1501 and second semiconductor device 1503 share a same gate structure 1506 extending in a third direction (e.g., vertically) to encompass both nanoribbons 1502a and 1502b, and also extending in the second direction (e.g., into and out of the page). In general, the description of semiconductor devices 102 and 104 from FIGS. 1B and 1C apply respectively to semiconductor devices 1501 and 1503. In some embodiments, a dielectric layer 1508 is present between first source or drain regions 1504a and second source or drain regions 1504b along the third direction to electrically isolate the regions from each other. First semiconductor device 1501 may have first fin isolation structures 1509 on either side along the first direction that include a dielectric material 1510 around an airgap 1512. The description above for dielectric material 1102 and airgap 1104 from FIG. 11A applies respectively to dielectric material 1510 and airgap 1512. According to some embodiments, second semiconductor device 1503 has second fin isolation structures 1511 on either side along the first direction that include a first dielectric material 1514 around a second dielectric material 1516. The description above for first dielectric material 1302 and second dielectric material 1304 from FIG. 13B applies respectively to first dielectric material 1514 and second dielectric material 1516. Note that the first fin isolation structures 1509 may be formed directly on second fin isolation structures 1511, such that a bottom surface of first fin isolation structures 1509 directly abuts a top surface of second fin isolation structures 1511.

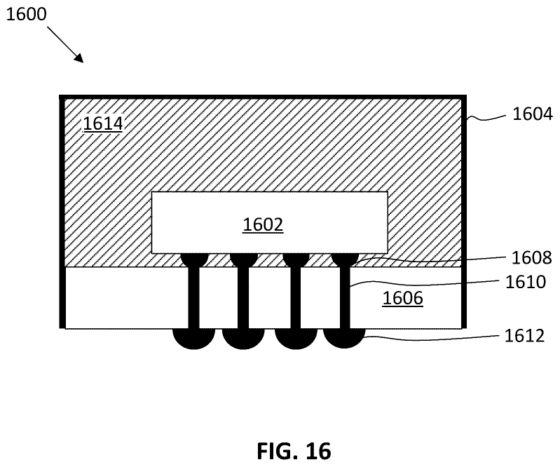

FIG. 16 illustrates an example embodiment of a chip package 1600, in accordance with an embodiment of the present disclosure. As can be seen, chip package 1600 includes one or more dies 1602. One or more dies 1602 may include at least one integrated circuit having semiconductor devices, such as any of the semiconductor devices disclosed herein. One or more dies 1602 may include any other circuitry used to interface with other devices formed on the dies, or other devices connected to chip package 1600, in some example configurations.

As can be further seen, chip package 1600 includes a housing 1604 that is bonded to a package substrate 1606. The housing 1604 may be any standard or proprietary housing, and may provide, for example, electromagnetic shielding and environmental protection for the components of chip package 1600. The one or more dies 1602 may be conductively coupled to a package substrate 1606 using connections 1608, which may be implemented with any number of standard or proprietary connection mechanisms, such as solder bumps, ball grid array (BGA), pins, or wire bonds, to name a few examples. Package substrate 1606 may be any standard or proprietary package substrate, but in some cases includes a dielectric material having conductive pathways (e.g., including conductive vias and lines) extending through the dielectric material between the faces of package substrate 1606, or between different locations on each face. In some embodiments, package substrate 1606 may have a thickness less than 1 millimeter (e.g., between 0.1 millimeters and 0.5 millimeters), although any number of package geometries can be used. Additional conductive contacts 1612 may be disposed at an opposite face of package substrate 1606 for conductively contacting, for instance, a printed circuit board (PCB). One or more vias 1610 extend through a thickness of package substrate 1606 to provide conductive pathways between one or more of connections 1608 to one or more of contacts 1612. Vias 1610 are illustrated as single straight columns through package substrate 1606 for ease of illustration, although other configurations can be used (e.g., damascene, dual damascene, through-silicon via, or an interconnect structure that meanders through the thickness of substrate 1606 to contact one or more intermediate locations therein). In still other embodiments, vias 1610 are fabricated by multiple smaller stacked vias, or are staggered at different locations across package substrate 1606. In the illustrated embodiment, contacts 1612 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1612, to inhibit shorting.

In some embodiments, a mold material 1614 may be disposed around the one or more dies 1602 included within housing 1604 (e.g., between dies 1602 and package substrate 1606 as an underfill material, as well as between dies 1602 and housing 1604 as an overfill material). Although the dimensions and qualities of the mold material 1614 can vary from one embodiment to the next, in some embodiments, a thickness of mold material 1614 is less than 1 millimeter. Example materials that may be used for mold material 1614 include epoxy mold materials, as suitable. In some cases, the mold material 1614 is thermally conductive, in addition to being electrically insulating.

### Methodology

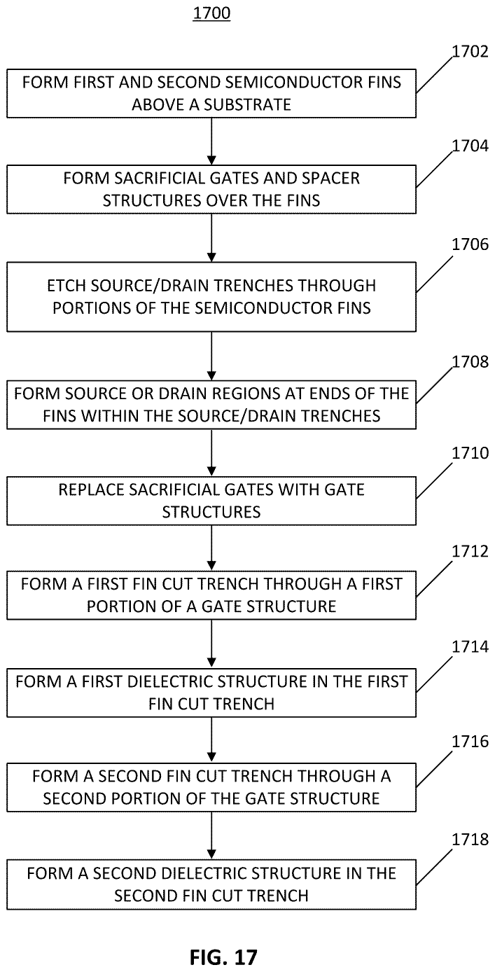

FIG. 17 is a flow chart of a method 1700 for forming at least a portion of an integrated circuit, according to an embodiment. Various operations of method 1700 may be illustrated in FIG. 2A-14A and 2B-14B. However, the correlation of the various operations of method 1700 to the specific components illustrated in the aforementioned figures is not intended to imply any structural and/or use limitations. Rather, the aforementioned figures provide one example embodiment of method 1700. Other operations may be performed before, during, or after any of the operations of method 1700. For example, method 1700 does not explicitly describe all processes that are performed to form common transistor structures. Some of the operations of method 1700 may be performed in a different order than the illustrated order.

Method 1700 begins with operation 1702 where any number of parallel semiconductor fins are formed, such as first and second fins, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. The alternating layers can be blanket deposited and then etched into fins, or deposited into fin-shaped trenches. The fins may also include a cap structure over each fin that is used to define the locations of the fins during, for example, an RIE process. The cap structure may be a dielectric material, such as silicon nitride.

According to some embodiments, a dielectric layer is formed around subfin portions of each of the first and second fins. In some embodiments, the dielectric layer extends between each pair of adjacent parallel fins and runs lengthwise in the same direction as the fins. In some embodiments, the anisotropic etching process that forms the fins also etches into a portion of the substrate and the dielectric layer may be formed within the recessed portions of the substrate. Accordingly, the dielectric layer acts as shallow trench isolation (STI) between adjacent fins. The dielectric layer may be any suitable dielectric material, such as silicon dioxide.

Method 1700 continues with operation 1704 where sacrificial gates and spacer structures are formed over the fins. The sacrificial gates may be patterned using gate masking layers in strips that run orthogonally over the fins (e.g., forming a cross-hatch pattern with the fins). The gate masking layers may be any suitable hard mask material, such as carbon hard mask (CHM) or silicon nitride. The sacrificial gates may be formed from any suitable material that can be selectively removed at a later time without damaging the semiconductor material of the fins. In one example, the sacrificial gates include polysilicon. The spacer structures may be deposited and then etched back such that the spacer structures remain mostly only on sidewalls of any exposed structures. According to some embodiments, the spacer structures may be any suitable dielectric material, such as silicon nitride or silicon oxynitride.

Method 1700 continues with operation 1706 where source/drain trenches are etched through exposed portions of the semiconductor fins. The exposed fin portions not protected beneath the sacrificial gates (and any spacer structures on the sides of the sacrificial gates) may be removed using any anisotropic etching process, such as reactive ion etching (RIE) or other directional etch process. The removal of the exposed fin portions creates source or drain trenches that alternate with gate trenches (currently filled with the sacrificial gates) along the first direction, according to some embodiments. In some embodiments, at least a portion of the subfin regions is also removed such that a top surface of the subfin regions is recessed below a top surface of the adjacent dielectric layer.

Method 1700 continues with operation 1708 where source or drain regions are formed at the ends of the semiconductor regions of each of the fins. The source or drain regions may be epitaxially grown from the exposed ends of the semiconductor layers within the source/drain trenches. In some example embodiments, the source or drain regions are n-type source or drain regions (e.g., epitaxial silicon) or p-type source or drain regions (e.g., epitaxial SiGe). According to some embodiments, the first fin includes n-type source or drain regions (in order to form an NMOS device), and the second fin includes p-type source or drain regions (in order to form a PMOS device).

Another dielectric fill may be formed adjacent to the various source or drain regions for additional electrical isolation between adjacent regions. The dielectric fill may also extend over a top surface of the source or drain regions. In some embodiments, topside conductive contacts may be formed through the dielectric fill to contact one or more of the source or drain regions.

Method 1700 continues with operation 1710 where the sacrificial gates are removed. The sacrificial gates may be removed using an isotropic etching process that selectively removes all of the material from the sacrificial gates, thus exposing the various fins between the set of spacer structures. In the example case where GAA transistors are used, any sacrificial layers within the exposed fins between the spacer structures may also be removed to release nanoribbons, nanosheets, or nanowires of semiconductor material.

According to some embodiments, gate structures are formed in place of the sacrificial gates around the semiconductor regions of the first and second fins within the gate trench. The gate structures may include both a gate dielectric and a gate electrode. The gate dielectric is first formed over the exposed semiconductor regions between the spacer structures followed by forming the gate electrode within the remainder of the gate trench, according to some embodiments. The gate dielectric may include any number of dielectric layers deposited using a CVD process, such as ALD. The gate electrode can include any number of conductive material layers, such as any metals, metal alloys, or polysilicon. The gate electrode may be deposited using electroplating, electroless plating, CVD, ALD, PECVD, or PVD, to name a few examples. The gate electrode may include one or more workfunction layers that differ between NMOS and PMOS devices.

Method 1700 continues with operation 1712 where a first fin cut trench is formed through at least a portion of one of the gate structures. According to some embodiments, the first fin cut trench extends in a second direction (e.g., the same direction as the gate structure) to remove a portion of the gate structure. The first fin cut trench may also cut through one or more semiconductor regions of corresponding fins, thus removing those semiconductor regions from within the gate trench. In some examples, the first fin cut trench extends along the second direction between gate cuts that extend along the first direction across the gate structures. In some examples, the first fin cut trench extends along the second direction through any number of devices. According to some embodiments, the first fin cut trench extends through at least an entire thickness of the gate structure and may extend into at least a portion of the underlying subfin region or at least a portion of the substrate. The width of the first fin cut trench (e.g., along the first direction) may be substantially equal to the entire width of the gate trench between the spacer structures.

Method 1700 continues with operation 1714 where a first dielectric structure is formed within the first fin cut trench. According to some embodiments, the first dielectric structure includes one or more dielectric materials and/or airgaps to impose a tensile stress on adjacent devices along the first direction. Example materials and arrangements for the first dielectric structure are provided above with reference to first fin isolation structure 114a or first fin isolation structure 1101.

Method 1700 continues with operation 1716 where a second fin cut trench is formed through at least a portion of one of the gate structures. According to some embodiments, the second fin cut trench extends in the second direction (e.g., the same direction as the gate structure) to remove a portion of the gate structure. The second fin cut trench may also cut through one or more semiconductor regions of corresponding fins, thus removing those semiconductor regions from within the gate trench. In some examples, the second fin cut trench extends along the second direction between gate cuts that extend along the first direction across the gate structures. In some examples, the second fin cut trench extends along the second direction and abuts directly against first dielectric structure, such that the second fin trench extends colinearly with the first dielectric structure along the second direction. According to some embodiments, the second fin cut trench extends through at least an entire thickness of the gate structure and may extend into at least a portion of the underlying subfin region or at least a portion of the substrate. The width of the second fin cut trench (e.g., along the first direction) may be substantially equal to the entire width of the gate trench between the spacer structures.

Method 1700 continues with operation 1718 where a second dielectric structure is formed within the second fin cut trench. According to some embodiments, the second dielectric structure includes one or more dielectric materials to impose a compressive stress on adjacent devices along the first direction. Example materials and arrangements for the second dielectric structure are provided above with reference to second fin isolation structure 114b or second fin isolation structure 1301. Both the first dielectric structure and the second dielectric structure may occupy portions of the same gate trench, such that the structure are colinearly aligned along the second direction.

### Example System

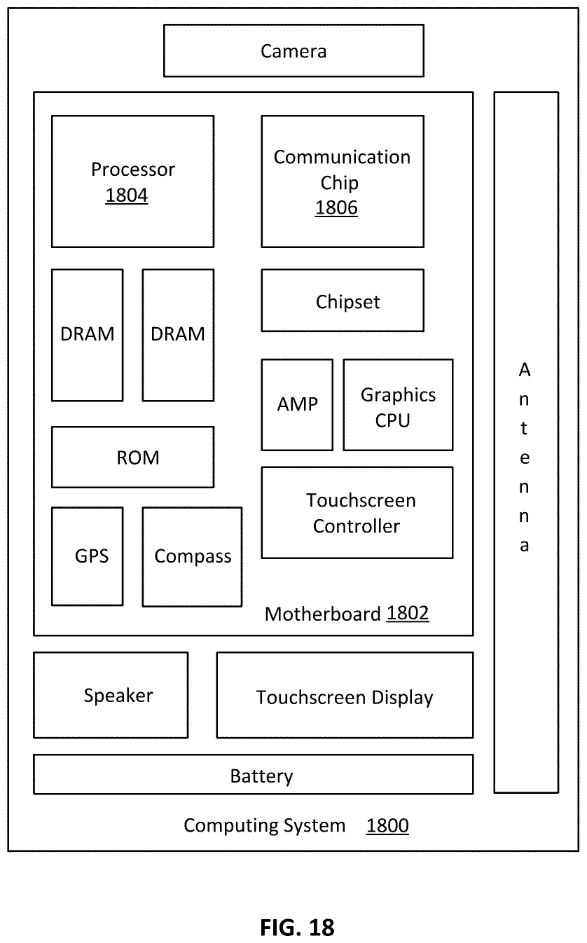

FIG. 18 is an example computing system implemented with one or more of the integrated circuit structures as disclosed herein, in accordance with some embodiments of the present disclosure. As can be seen, the computing system 1800 houses a motherboard 1802. The motherboard 1802 may include a number of components, including, but not limited to, a processor 1804 and at least one communication chip 1806, each of which can be physically and electrically coupled to the motherboard 1802, or otherwise integrated therein. As will be appreciated, the motherboard 1802 may be, for example, any printed circuit board (PCB), whether a main board, a daughterboard mounted on a main board, or the only board of system 1800, etc.

Depending on its applications, computing system 1800 may include one or more other components that may or may not be physically and electrically coupled to the motherboard 1802. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1800 may include one or more integrated circuit structures or devices configured in accordance with an example embodiment, such as a module including an integrated circuit on a substrate, the substrate having semiconductor devices that include one or more fin isolation structures having different dielectric materials to impose either tensile or compressive strain on adjacent devices. In some embodiments, multiple functions can be integrated into one or more chips (e.g., for instance, note that the communication chip 1806 can be part of or otherwise integrated into the processor 1804).

The communication chip 1806 enables wireless communications for the transfer of data to and from the computing system 1800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1806 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1800 may include a plurality of communication chips 1806. For instance, a first communication chip 1806 may be dedicated to shorter range wireless communications such as Wi-Fi and Bluetooth and a second communication chip 1806 may be dedicated to longer range wireless communications such as GPS, EDGE, GPRS, CDMA, WiMAX, LTE, Ev-DO, and others.

The processor 1804 of the computing system 1800 includes an integrated circuit die packaged within the processor 1804. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 1806 also may include an integrated circuit die packaged within the communication chip 1806. In accordance with some such example embodiments, the integrated circuit die of the communication chip includes one or more semiconductor devices as variously described herein. As will be appreciated in light of this disclosure, note that multi-standard wireless capability may be integrated directly into the processor 1804 (e.g., where functionality of any chips 1806 is integrated into processor 1804, rather than having separate communication chips). Further note that processor 1804 may be a chip set having such wireless capability. In short, any number of processor 1804 and/or communication chips 1806 can be used. Likewise, any one chip or chip set can have multiple functions integrated therein.

In various implementations, the computing system 1800 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 1800 may be combined or integrated in a system-on-a-chip (SoC) architecture. In some embodiments, the components may be hardware components, firmware components, software components or any suitable combination of hardware, firmware or software.

### FURTHER EXAMPLE EMBODIMENTS

The following examples pertain to further embodiments, from which numerous permutations and configurations will be apparent.

Example 1 is an integrated circuit that includes a first semiconductor device region extending from a first source or drain region in a first direction, a second semiconductor region extending from a second source or drain region in the first direction, a first gate structure extending in a second direction over the first semiconductor region, a second gate structure extending in the second direction over the second semiconductor region, a first dielectric structure extending in the second direction adjacent to the first source or drain region, and a second dielectric structure extending in the second direction adjacent to the second source or drain region. The first dielectric structure exerts a compressive stress on the first semiconductor region and the second dielectric structure exerts a tensile stress on the second semiconductor region.

Example 2 includes the integrated circuit of Example 1, wherein the first semiconductor region comprises one or more first semiconductor nanoribbons and the second semiconductor region comprises one or more second semiconductor nanoribbons.

Example 3 includes the integrated circuit of Example 2, wherein the one or more first semiconductor nanoribbons and the one or more second semiconductor nanoribbons comprises germanium, silicon, or any combination thereof.

Example 4 includes the integrated circuit of any one of Examples 1-3, wherein the first semiconductor region extends from the first source or drain region to a third source or drain region along the first direction, and the second semiconductor region extends from the second source or drain region to a fourth source or drain region along the first direction.

Example 5 includes the integrated circuit of Example 4, wherein the first and third source or drain regions are p-type source or drain regions, and the second and fourth source or drain regions are n-type source or drain regions.

Example 6 includes the integrated circuit of Example 4 or 5, further comprising: a third dielectric structure extending in the second direction adjacent to the third source or drain region, the third dielectric structure exerting a compressive stress on the first semiconductor region; and a fourth dielectric structure extending in the second direction adjacent to the fourth source or drain region, the fourth dielectric structure exerting a tensile stress on the second semiconductor region.

Example 7 includes the integrated circuit of any one of Examples 1-6, wherein the first source or drain region and the second source or drain region are adjacent along the second direction.

Example 8 includes the integrated circuit of any one of Examples 1-7, wherein the first dielectric structure and the second dielectric structure are colinear along the second direction.

Example 9 includes the integrated circuit of any one of Examples 1-8, further comprising: a third semiconductor region extending in the first direction from the first source or drain region to the first dielectric structure; and a fourth semiconductor region extending in the first direction from the second source or drain region to the second dielectric structure.

Example 10 includes the integrated circuit of any one of Examples 1-9, wherein the first dielectric structure comprises an outer dielectric layer having silicon and nitrogen, and an inner dielectric layer having silicon and oxygen.

Example 11 includes the integrated circuit of any one of Examples 1-10, wherein the second dielectric structure comprises an outer dielectric layer having silicon and nitrogen around an airgap.

Example 12 includes the integrated circuit of any one of Examples 1-11, further comprising a gate cut extending in the first direction between the first gate structure and the second gate structure and extending through an entire height of each of the first gate structure and second gate structure.

Example 13 includes the integrated circuit of Example 12, wherein the gate cut comprises an outer dielectric layer having silicon and nitrogen around an airgap.

Example 14 includes the integrated circuit of any one of Examples 1-13, wherein the second source or drain region is arranged over the first source or drain region in a third direction orthogonal to the first and second directions, and the second dielectric structure is arranged over the first dielectric structure in the third direction.

Example 15 is a die that includes the integrated circuit of any one of Examples 1-14.

Example 16 is an electronic device that includes a chip package having one or more dies. At least one of the one or more dies includes a first semiconductor device having a first semiconductor region extending from a first source or drain region to a second source or drain region in a first direction and a first gate structure extending over the first semiconductor region in a second direction substantially orthogonal to the first direction, a second semiconductor device having a second semiconductor region extending from a third source or drain region to a fourth source or drain region in the first direction and a second gate structure extending over the second semiconductor region in the second direction, a first dielectric structure adjacent to the first source or drain region, and a second dielectric structure adjacent to the third source or drain region and colinearly aligned with the first dielectric structure. The first dielectric structure exerts a compressive stress on the first semiconductor region and the second dielectric structure exerts a tensile stress on the second semiconductor region.

Example 17 includes the electronic device of Example 16, wherein the first semiconductor region comprises one or more first semiconductor nanoribbons and the second semiconductor region comprises one or more second semiconductor nanoribbons.

Example 18 includes the electronic device of Example 17, wherein the one or more first semiconductor nanoribbons and the one or more second semiconductor nanoribbons comprises germanium, silicon, or any combination thereof.

Example 19 includes the electronic device of any one of Examples 16-18, wherein the first and second source or drain regions are p-type source or drain regions, and the third and fourth source or drain regions are n-type source or drain regions.

Example 20 includes the electronic device of Example 19, wherein the at least one of the one or more dies further comprises: a third dielectric structure adjacent to the second source or drain region, the third dielectric structure exerting a compressive stress on the first semiconductor region; and a fourth dielectric structure adjacent to the fourth source or drain region and colinearly aligned with the third dielectric structure, the fourth dielectric structure exerting a tensile stress on the second semiconductor region.

Example 21 includes the electronic device of any one of Examples 16-20, wherein the first source or drain region and the third source or drain region are adjacent along the second direction, and the second source or drain region and the fourth source or drain region are adjacent along the second direction.

Example 22 includes the electronic device of any one of Examples 16-21, wherein the first dielectric structure and the second dielectric structure are colinear along the second direction.

Example 23 includes the electronic device of any one of Examples 16-22, wherein the at least one of the one or more dies further comprises: a third semiconductor region extending in the first direction from the first source or drain region to the first dielectric structure; and a fourth semiconductor region extending in the first direction from the third source or drain region to the second dielectric structure.

Example 24 includes the electronic device of any one of Examples 16-23, wherein the first dielectric structure comprises an outer dielectric layer having silicon and nitrogen, and an inner dielectric layer having silicon and oxygen.

Example 25 includes the electronic device of any one of Examples 16-24, wherein the second dielectric structure comprises an outer dielectric layer having silicon and nitrogen around an airgap.

Example 26 includes the electronic device of any one of Examples 16-25, wherein the at least one of the one or more dies further comprises a gate cut extending in the first direction between the first gate structure and the second gate structure and extending through an entire height of each of the first gate structure and second gate structure.

Example 27 includes the electronic device of Example 26, wherein the gate cut comprises an outer dielectric layer having silicon and nitrogen around an airgap.

Example 28 includes the electronic device of any one of Examples 16-27, wherein the third source or drain region is arranged over the first source or drain region in a third direction orthogonal to the first and second directions, the fourth source or drain region is arranged over the second source or drain region in the third direction, and the second dielectric structure is arranged over the first dielectric structure in the third direction.

Example 29 includes the electronic device of any one of Examples 16-28, further comprising a printed circuit board, wherein the chip package is attached to the printed circuit board.

Example 30 is a method of forming an integrated circuit. The method includes forming first and second adjacent fins comprising semiconductor material, the fins extending above a substrate and each extending parallel to one another in a first direction; forming a first sacrificial gate and a second sacrificial gate each extending in a second direction over the semiconductor material of the first and second adjacent fins; forming spacer structures on sidewalls of the first and second sacrificial gates; etching through exposed portions of the first and second fins not protected by the first and second sacrificial gates and spacer structures; forming source or drain regions at exposed ends of the first and second fins; replacing the first sacrificial gate with a first gate structure and the second sacrificial gate with a second gate structure; removing a first portion of the second gate structure and any portion of the first fin that had been covered by the first portion of the second gate structure to form a first fin cut trench; forming a first dielectric structure in the first fin cut trench that is aligned with the first fin along the first direction; removing a second portion of the second gate structure and any portion of the second fin that had been covered by the second portion of the second gate structure to form a second fin cut trench; and forming a second dielectric structure in the second fin cut trench that is aligned with the second fin along the first direction. The second dielectric structure has a different material composition compared to the first dielectric structure.

Example 31 includes the method of Example 30, wherein the first dielectric structure exerts a compressive stress on the semiconductor material of the first fin, and the second dielectric structures exerts a tensile stress on the semiconductor material of the second fin.

Example 32 includes the method of Example 30 or 31, wherein forming the first dielectric structure comprises forming an outer dielectric layer having silicon and nitrogen, and forming an inner dielectric layer having silicon and oxygen.

Example 33 includes the method of any one of Examples 30-32, wherein forming the second dielectric structure comprises forming an outer dielectric layer having silicon and nitrogen and leaving an airgap in a central portion of the second dielectric structure.

Example 34 includes the method of any one of Examples 30-33, further comprising: etching a trench extending along the first direction through the first gate structure between the first and second fins; forming an outer dielectric layer in the trench that includes silicon and nitrogen; and leaving an airgap in a central portion of the trench.

Example 35 is an integrated circuit that includes a first semiconductor region extending from a first source or drain region to a second source or drain region in a first direction, a second semiconductor region extending from a third source or drain region to a fourth source or drain region in the first direction, a first gate structure extending over the first semiconductor region in a second direction, a second gate structure extending over the second semiconductor region in the second direction, a first dielectric structure extending in the second direction adjacent to the first source or drain region, a second dielectric structure extending in the second direction adjacent to the second source or drain region, a third dielectric structure extending in the second direction adjacent to the third source or drain region, and a fourth dielectric structure extending in the second direction adjacent to the fourth source or drain region. The first and third dielectric structures have different material compositions and are colinear with one another, and the second and fourth dielectric structures have different material compositions and are colinear with one another.

Example 36 includes the integrated circuit of Example 35, wherein the first semiconductor region comprises one or more first semiconductor nanoribbons and the second semiconductor region comprises one or more second semiconductor nanoribbons.

Example 37 includes the integrated circuit of Example 36, wherein the one or more first semiconductor nanoribbons and the one or more second semiconductor nanoribbons comprises germanium, silicon, or any combination thereof.

Example 38 includes the integrated circuit of any one of Examples 35-37, wherein the first and second dielectric structures exert a compressive force on the first semiconductor region, and the third and fourth dielectric structures exert a tensile force on the second semiconductor region.

Example 39 includes the integrated circuit of Example 38, wherein the first and second source or drain regions are p-type source or drain regions, and the second and fourth source or drain regions are n-type source or drain regions.

Example 40 includes the integrated circuit of Example 38 or 39, wherein the first source or drain region and the third source or drain region are adjacent along the second direction, and the second source or drain region and the fourth source or drain region are adjacent along the second direction.

Example 41 includes the integrated circuit of any one of Examples 35-40, wherein the first dielectric structure and the third dielectric structure are colinear along the second direction, and the second dielectric structure and the fourth dielectric structure are colinear along the second direction.

Example 42 includes the integrated circuit of any one of Examples 35-41, further comprising: a third semiconductor region extending in the first direction from the first source or drain region to the first dielectric structure; a fourth semiconductor region extending in the first direction from the second source or drain region to the second dielectric structure; a fifth semiconductor region extending in the first direction from the third source or drain region to the third dielectric structure; and a sixth semiconductor region extending in the first direction from the fourth source or drain region to the fourth dielectric structure.

Example 43 includes the integrated circuit of any one of Examples 35-42, wherein the first and second dielectric structures each comprise an outer dielectric layer having silicon and nitrogen, and an inner dielectric layer having silicon and oxygen.

Example 44 includes the integrated circuit of Example 43, wherein the third and fourth dielectric structures each comprise an outer dielectric layer having silicon and nitrogen around an airgap.

Example 45 includes the integrated circuit of any one of Examples 35-44, further comprising a gate cut extending in the first direction between the first gate structure and the second gate structure and extending through an entire height of each of the first gate structure and second gate structure.

Example 46 includes the integrated circuit of Example 45, wherein the gate cut comprises an outer dielectric layer having silicon and nitrogen around an airgap.

Example 47 includes the integrated circuit of any one of Examples 35-46, wherein the third source or drain region is arranged over the first source or drain region in a third direction orthogonal to the first and second directions, the fourth source or drain region is arranged over the second source or drain region in the third direction, the third dielectric structure is arranged over the first dielectric structure in the third direction, and the fourth dielectric structure is arranged over the second dielectric structure in the third direction.

Example 48 is a die that includes the integrated circuit of any one of Examples 35-47.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a first semiconductor region extending from a first source or drain region in a first direction;
a second semiconductor region extending from a second source or drain region in the first direction;
a first gate structure extending over the first semiconductor region in a second direction, and a second gate structure extending over the second semiconductor region in the second direction;
a first dielectric structure extending in the second direction adjacent to the first source or drain region, the first dielectric structure exerting a compressive stress on the first semiconductor region; and
a second dielectric structure extending in the second direction adjacent to the second source or drain region, the second dielectric structure exerting a tensile stress on the second semiconductor region.

2. The integrated circuit of claim 1, wherein the first semiconductor region extends from the first source or drain region to a third source or drain region along the first direction, and the second semiconductor region extends from the second source or drain region to a fourth source or drain region along the first direction.

3. The integrated circuit of claim 2, wherein the first and third source or drain regions are p-type source or drain regions, and the second and fourth source or drain regions are n-type source or drain regions.

4. The integrated circuit of claim 2, further comprising:
a third dielectric structure extending in the second direction adjacent to the third source or drain region, the third dielectric structure exerting a compressive stress on the first semiconductor region; and
a fourth dielectric structure extending in the second direction adjacent to the fourth source or drain region, the fourth dielectric structure exerting a tensile stress on the second semiconductor region.

5. The integrated circuit of claim 1, wherein the first dielectric structure and the second dielectric structure are colinear along the second direction.

6. The integrated circuit of claim 1, wherein the first dielectric structure comprises an outer dielectric layer having silicon and nitrogen, and an inner dielectric layer having silicon and oxygen.

7. The integrated circuit of claim 1, wherein the second dielectric structure comprises an outer dielectric layer having silicon and nitrogen around an airgap.

8. The integrated circuit of claim 1, further comprising a gate cut extending in the first direction between the first gate structure and the second gate structure and extending through an entire height of each of the first gate structure and second gate structure, wherein the gate cut comprises an outer dielectric layer having silicon and nitrogen around an airgap.

9. The integrated circuit of claim 1, wherein the second source or drain region is arranged over the first source or drain region in a third direction orthogonal to the first and second directions, and the second dielectric structure is arranged over the first dielectric structure in the third direction.

10. An electronic device, comprising:
a chip package comprising one or more dies, at least one of the one or more dies comprising
a first semiconductor device having a first semiconductor region extending from a first source or drain region to a second source or drain region in a first direction and a first gate structure extending over the first semiconductor region in a second direction substantially orthogonal to the first direction;
a second semiconductor device having a second semiconductor region extending from a third source or drain region to a fourth source or drain region in the first direction and a second gate structure extending over the second semiconductor region in the second direction;
a first dielectric structure adjacent to the first source or drain region, the first dielectric structure exerting a compressive stress on the first semiconductor region; and
a second dielectric structure adjacent to the third source or drain region and colinearly aligned with the first dielectric structure, the second dielectric structure exerting a tensile stress on the second semiconductor region.

11. The electronic device of claim 10, wherein the at least one of the one or more dies further comprises:
a third dielectric structure adjacent to the second source or drain region, the third dielectric structure exerting a compressive stress on the first semiconductor region; and
a fourth dielectric structure adjacent to the fourth source or drain region and colinearly aligned with the third dielectric structure, the fourth dielectric structure exerting a tensile stress on the second semiconductor region.

12. The electronic device of claim 10, wherein the first dielectric structure and the second dielectric structure are colinear along the second direction.

13. The electronic device of claim 10, wherein the at least one of the one or more dies further comprises:
a third semiconductor region extending in the first direction from the first source or drain region to the first dielectric structure; and
a fourth semiconductor region extending in the first direction from the third source or drain region to the second dielectric structure.

14. The electronic device of claim 10, wherein the third source or drain region is arranged over the first source or drain region in a third direction orthogonal to the first and second directions, the fourth source or drain region is arranged over the second source or drain region in the third direction, and the second dielectric structure is arranged over the first dielectric structure in the third direction.

15. An integrated circuit comprising:
a first semiconductor region extending from a first source or drain region to a second source or drain region in a first direction;
a second semiconductor region extending from a third source or drain region to a fourth source or drain region in the first direction;
a first gate structure extending over the first semiconductor region in a second direction, and a second gate structure extending over the second semiconductor region in the second direction;
a first dielectric structure extending in the second direction adjacent to the first source or drain region;
a second dielectric structure extending in the second direction adjacent to the second source or drain region;
a third dielectric structure extending in the second direction adjacent to the third source or drain region; and
a fourth dielectric structure extending in the second direction adjacent to the fourth source or drain region,
wherein the first and third dielectric structures have different material compositions and are colinear with one another, and the second and fourth dielectric structures have different material compositions and are colinear with one another.

16. The integrated circuit of claim 15, wherein the first and second dielectric structures exert a compressive force on the first semiconductor region, and the third and fourth dielectric structures exert a tensile force on the second semiconductor region.

17. The integrated circuit of claim 15, wherein the first dielectric structure and the third dielectric structure are colinear along the second direction, and the second dielectric structure and the fourth dielectric structure are colinear along the second direction.

18. The integrated circuit of claim 15, further comprising:
a third semiconductor region extending in the first direction from the first source or drain region to the first dielectric structure;
a fourth semiconductor region extending in the first direction from the second source or drain region to the second dielectric structure;
a fifth semiconductor region extending in the first direction from the third source or drain region to the third dielectric structure; and
a sixth semiconductor region extending in the first direction from the fourth source or drain region to the fourth dielectric structure.

19. The integrated circuit of claim 18, wherein the third and fourth dielectric structures each comprise an outer dielectric layer having silicon and nitrogen around an airgap.

20. The integrated circuit of claim 15, further comprising a gate cut extending in the first direction between the first gate structure and the second gate structure and extending through an entire height of each of the first gate structure and second gate structure, wherein the gate cut comprises an outer dielectric layer having silicon and nitrogen around an airgap.
